(19) United States
(12) Patent Application Publication
(10) Pub. No.: US 2023/0058116 A1
(43) Pub. Date: Feb. 23, 2023

(54) SEMICONDUCTOR DEVICE

(71) Applicant: SAMSUNG ELECTRONICS CO., LTD., Suwon-Si (KR)

(72) Inventors: HONG SIK SHIN, Seoul (KR); Sung Woo KANG, Suwon-Si (KR); Dong Kwon KIM, Suwon-Si (KR)

(21) Appl. No.: 17/659,135

(22) Filed: Apr. 13, 2022

(30) Foreign Application Priority Data
Aug. 18, 2021 (KR) 10-2021-0108731

(51) Int. Cl. H01L 29/417

(52) U.S. Cl. CPC H01L 29/41733; H01L 29/41775

(57) ABSTRACT

A semiconductor device includes a substrate, an active pattern disposed on the substrate and that extends in a first horizontal direction, a field insulating layer disposed on the substrate and that surrounds a sidewall of the active pattern, a gate electrode disposed on the field insulating layer and that extends in a second horizontal direction, a source/drain region disposed on a side of the gate electrode, a first interlayer insulating layer disposed on the field insulating layer and that surrounds a portion of a sidewall of the source/drain region, a second interlayer insulating layer disposed on the first interlayer insulating layer and that surrounds a sidewall of the gate electrode, and a source/drain contact that penetrates through the second interlayer insulating layer and is electrically connected to the source/drain region. The source/drain contact includes a skirt that protrudes from a lower sidewall toward the second interlayer insulating.

### CROSS-REFERENCE TO RELATED APPLICATION

This application claims priority under 35 U.S.C. § 119 from Korean Patent Application No. 10-2021-0108731, filed on Aug. 18, 2021 in the Korean Intellectual Property Office, the contents of which are herein incorporated by reference in their entirety.

### TECHNICAL FIELD

Embodiments of the present disclosure are directed to a semiconductor device, and more particularly, to a semiconductor device that includes a multi-bridge channel field effect transistor (MBCFET™)

### DISCUSSION OF THE RELATED ART

Recently, with the rapid dissemination of information media, functions of a semiconductor device have been also rapidly developed. For recent semiconductor products, low cost is needed to ensure competitiveness and high product integration is needed for high quality. For high integration, the semiconductor device have been scaled down.

However, as a pitch size is reduced, means for reducing capacitance and ensuring electrical stability between contacts in the semiconductor device will be needed.

### BRIEF SUMMARY

Embodiments of the present disclosure provide a semiconductor device with improved reliability by preventing a capping pattern from being etched during a process of forming a source/drain contact to prevent short from occurring between a gate electrode and the source/drain contact.

According to some embodiments of the present disclosure, there is provided a semiconductor device that includes a substrate, an active pattern disposed on the substrate and that extends in a first horizontal direction, a field insulating layer disposed on the substrate and that surrounds a sidewall of the active pattern, a gate electrode disposed on the field insulating layer and that extends in a second horizontal direction different from the first horizontal direction, a source/drain region disposed on at least one side of the gate electrode, a first interlayer insulating layer disposed on the field insulating layer and that surrounds a portion of a sidewall of the source/drain region, a second interlayer insulating layer disposed on the first interlayer insulating layer and that surrounds a sidewall of the gate electrode, and a source/drain contact that penetrates through the second interlayer insulating layer in a vertical direction and is electrically connected to the source/drain region. The source/drain contact includes a skirt that protrudes from a lower sidewall toward the second interlayer insulating layer in a horizontal direction.

According to some embodiments of the present disclosure, there is provided a semiconductor device that includes a substrate, an active pattern disposed on the substrate and that extends in a first horizontal direction, a field insulating layer disposed on the substrate and that surrounds a sidewall of the active pattern, a gate electrode disposed on the field insulating layer and that extends in a second horizontal direction different from the first horizontal direction, a source/drain region disposed on at least one side of the gate electrode, a first interlayer insulating layer disposed on the field insulating layer and that surrounds a portion of a sidewall of the source/drain region, a second interlayer insulating layer disposed on the first interlayer insulating layer and that surrounds a sidewall of the gate electrode, and a source/drain contact that penetrates through the second interlayer insulating layer in a vertical direction and is electrically connected to the source/drain region. The source/drain contact includes a first portion disposed on the source/drain region and a second portion disposed on the first portion. The first portion includes first and second sidewalls that oppose each other in the second horizontal direction, and the second portion includes first and second sidewalls that oppose each other in the second horizontal direction. The first sidewall of the first portion is continuous with the first sidewall of the second portion, and the second sidewall of the first portion is continuous with the second sidewall of the second portion. A width of a lower surface of the first portion in the second horizontal direction is greater than a width of a lower surface of the second portion in the second horizontal direction.

According to some embodiments of the present disclosure, there is provided a semiconductor device that includes a substrate, an active pattern disposed on the substrate and that extends in a first horizontal direction, a field insulating layer disposed on the substrate and that surrounds a sidewall of the active pattern, a gate electrode disposed on the field insulating layer and that extends in a second horizontal direction different from the first horizontal direction, a plurality of nanosheets stacked and spaced apart from each other in a vertical direction on the active pattern and surrounded by the gate electrode, a source/drain region disposed on at least one side of the gate electrode, a first interlayer insulating layer disposed on the field insulating layer and that surrounds a portion of a sidewall of the source/drain region, a second interlayer insulating layer disposed on the first interlayer insulating layer and that surrounds a sidewall of the gate electrode, and a source/drain contact that penetrates through the second interlayer insulating layer in a vertical direction and is electrically connected to the source/drain region. the source/drain contact includes a first portion disposed on the source/drain region and a second portion disposed on the first portion wherein the source/drain contact includes a skirt that protrudes from a lower sidewall of the first portion toward the second interlayer insulating layer in a horizontal direction. The first portion includes first and second sidewalls that oppose each other in the second horizontal direction, and the second portion includes first and second sidewalls that oppose each other in the second horizontal direction. The first sidewall of the first portion is continuous with the first sidewall of the second portion, and the second sidewall of the first portion is continuous with the second sidewall of the second portion. A width of a lower surface of the first portion in the second horizontal direction is greater than a width of a lower surface of the second portion in the second horizontal direction.

### BRIEF DESCRIPTION OF THE DRAWINGS

FIG. 1 is a layout view of a semiconductor device according to some embodiments of the present disclosure.

FIG. 2 is a cross-sectional view taken along line A-A′ of FIG. 1.

FIG. 3 is a cross-sectional view taken along line B-B′ of FIG. 1.

FIG. 4 is a cross-sectional view taken along line C-C′ of FIG. 1.

FIG. 5 is an enlarged view of a region R of FIG. 4.

FIGS. 6 to 34 illustrate a method of manufacturing a semiconductor device according to some embodiments of the present disclosure.

FIG. 35 is a cross-sectional view of a semiconductor device according to some embodiments of the present disclosure.

FIGS. 36 and 37 are cross-sectional views of a semiconductor device according to some embodiments of the present disclosure.

FIGS. 38 and 39 are cross-sectional views of a semiconductor device according to some embodiments of the present disclosure.

FIG. 40 is a layout view of a semiconductor device according to some embodiments of the present disclosure.

FIG. 41 is a cross-sectional view taken along line D-D′ of FIG. 40.

FIG. 42 is a cross-sectional view taken along line E-E′ of FIG. 40.

FIG. 43 is a cross-sectional view taken along line F-F′ of FIG. 40.

### DETAILED DESCRIPTION OF THE DISCLOSURE

A semiconductor device according to some embodiments of the present disclosure includes a multi-bridge channel field effect transistor (MBCFET™) that includes a nanosheet and a fin-type transistor (FinFET) that includes a channel region of a fin-type pattern shape by way of example, but embodiments of the present disclosure are not limited thereto.

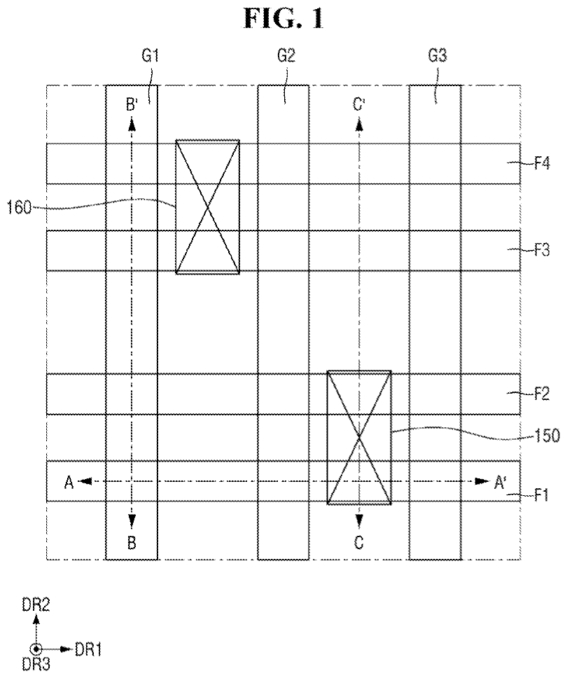

Hereinafter, a semiconductor device according to some embodiments will be described with reference to FIGS. 1 to 5.

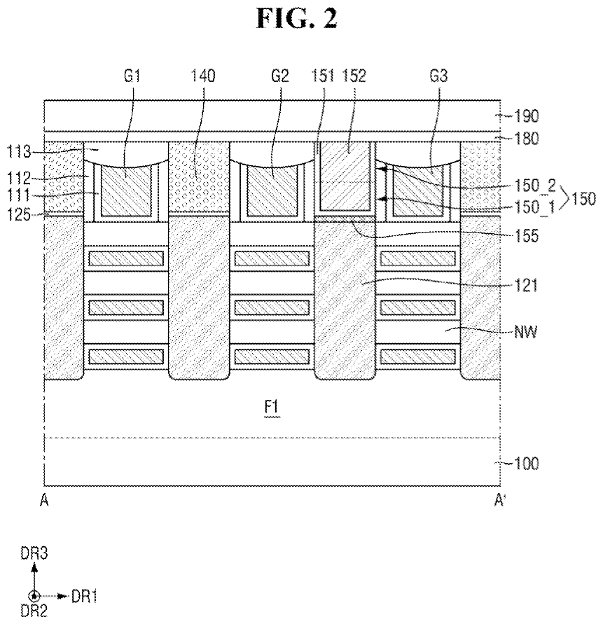

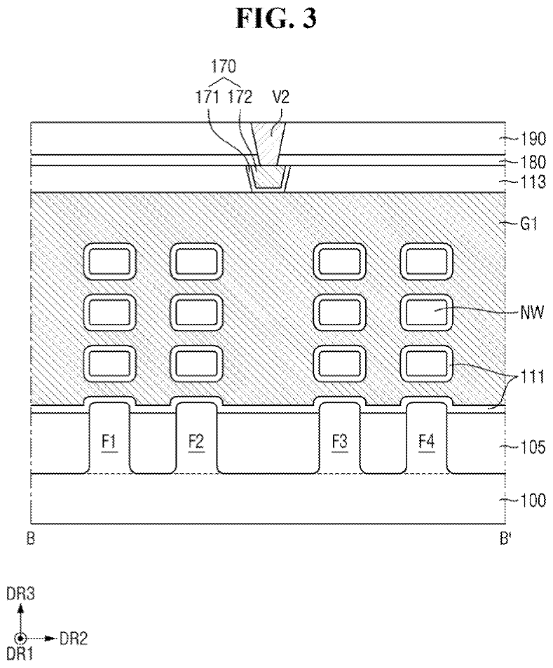

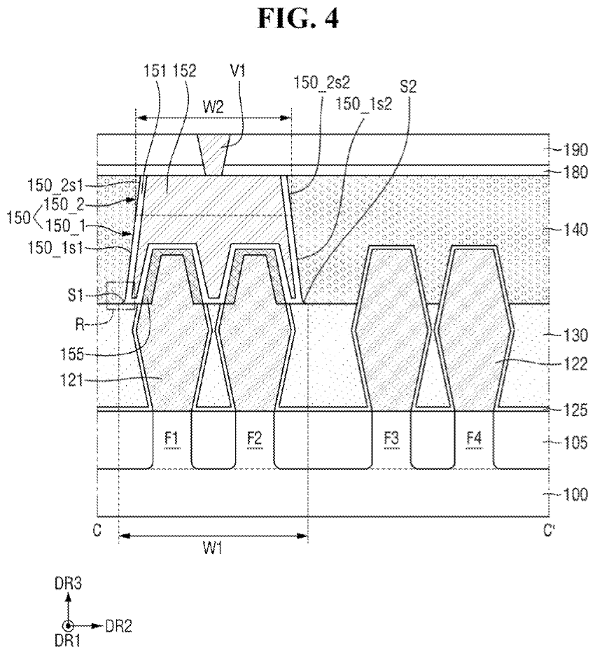

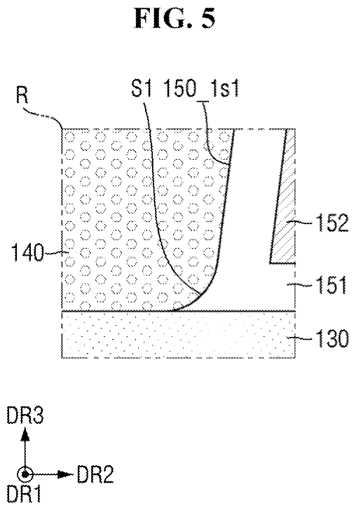

FIG. 1 is a layout view of a semiconductor device according to some embodiments of the present disclosure. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1. FIG. 5 is an enlarged view of a region R of FIG. 4.

Referring to FIGS. 1 to 5, a semiconductor device according to some embodiments of the present disclosure includes a substrate 100, first to fourth active patterns F1, F2, F3 and F4, a field insulating layer 105, a plurality of nanosheets NW, first to third gate electrodes G1, G2 and G3, a gate insulating layer 111, a gate spacer 12, a capping pattern 113, a first source/drain region 121, a second source/drain region 122, a first etch stop layer 125, a first interlayer insulating layer 130, a second interlayer insulating layer 140, a first source/drain contact 150, a silicide layer 155, a second source/drain contact 160, a gate contact 170, a second etch stop layer 180, a third interlayer insulating layer 190, a first via V1, and a second via V2.

The substrate 100 extends in a first horizontal direction DR1 and a second horizontal direction DR2 that crosses the first direction. The substrate 100 may be a silicon substrate or a silicon-on-insulator (SOI). Otherwise, the substrate 100 may include one or more of silicon germanium, silicon germanium on insulator (SGOI), indium antimonide, lead telluride compound, indium arsenide, indium phosphide, gallium arsenide or gallium antimonide, but embodiments of the present disclosure are not limited thereto.

Each of the first to fourth active patterns F1, F2, F3 and F4 protrudes from the substrate 100 in a vertical direction DR3 that is normal to the first direction DR1 and the second direction DR2. Each of the first to fourth active patterns F1, F2, F3 and F4 extends in the first horizontal direction DR1. The second active pattern F2 is spaced apart from the first active pattern F1 in the second horizontal direction DR2. The third active pattern F3 is spaced apart from the second active pattern F2 in the second horizontal direction DR2. The fourth active pattern F4 is spaced apart from the third active pattern F3 in the second horizontal direction DR2.

For example, an interval in the second horizontal direction DR2 between the first active pattern F1 and the second active pattern F2 may be smaller than that in the second horizontal direction DR2 between the second active pattern F2 and the third active pattern F3.

Each of the first to fourth active patterns F1, F2, F3 and F4 is a portion of the substrate 100, and includes an epitaxial layer grown from the substrate 100. Each of the first to fourth active patterns F1, F2, F3 and F4 includes silicon or germanium, which is an elemental semiconductor material. Each of the first to fourth active patterns F1, F2, F3 and F4 may include a compound semiconductor, and may include, for example, a group IV-IV compound semiconductor or a group III-V compound semiconductor.

The group IV-IV compound semiconductor may be a binary compound or ternary compound, which includes at least two or more of carbon (C), silicon (Si), germanium (Ge) or tin (Sn), or a compound that includes at least two or more of carbon (C), silicon (Si), germanium (Ge) or tin (Sn), which are doped with a group IV element. The group III-V compound semiconductor may be, for example, one of a binary compound, a ternary compound or a quaternary compound, which is formed by combination of at least one of aluminum (Al), gallium (Ga) or indium (in), which is a group III element, and one of phosphorus (P), arsenic (As) or antimony (Sb), which are group V elements.

The field insulating layer 105 is disposed on the substrate 100. The field insulating layer 105 surrounds a sidewall of each of the first to fourth active patterns F1, F2, F3 and F4. Each of the first to fourth active patterns F1, F2, F3 and F4 protrudes in the vertical direction DR3 above an upper surface of the field insulating layer 105. The field insulating layer 105 includes, for example, at least one of an oxide layer, a nitride layer, an oxynitride layer, or a combination layer thereof.

The plurality of nanosheets NW are disposed on the first to fourth active patterns F1, F2, F3 and F4, respectively. The plurality of nanosheets NW are stacked and spaced apart from each other in the vertical direction DR3. The plurality of nanosheets NW are disposed at locations where each of the first to fourth active patterns F1, F2, F3 and F4 and each of the first to third gate electrodes G1, G2 and G3 cross each other.

The plurality of nanosheets NW are spaced apart from each other in the first horizontal direction DR1 and the second horizontal direction DR2. For example, the plurality of nanosheets NW disposed where the first active pattern F1 and the first gate electrode G1 cross each other are spaced apart in the first horizontal direction DR1 from the plurality of nanosheets NW disposed where the first active pattern F1 and the second gate electrode G2 cross each other. In addition, the plurality of nanosheets NW disposed where the first active pattern F1 and the first gate electrode G1 cross each other are spaced apart in the second horizontal direction DR2 from the plurality of nanosheets NW disposed where the second active pattern F2 and the first gate electrode G1 cross each other.

Although FIGS. 2 and 3 show that the plurality of nanosheets NW include three nanosheets stacked and spaced apart from each other in the vertical direction DR3, this is for convenience of description, and embodiments of the present disclosure are not limited thereto. In some embodiments, the plurality of nanosheets NW may include four or more nanosheets stacked and spaced apart from each other in the vertical direction DR3.

Each of the first to third gate electrodes G1, G2 and G3 is disposed on the field insulating layer 105 and the first to fourth active patterns F1, F2, F3 and F4 and each extends in the second horizontal direction DR2. The second gate electrode G2 is spaced apart from the first gate electrode G1 in the first horizontal direction DR1. The third gate electrode G3 is spaced apart from the second gate electrode G2 in the first horizontal direction DR1. Each of the first to third gate electrodes G1, G2 and G3 surrounds the plurality of nanosheets NW.

Each of the first to third gate electrodes G1, G2 and G3 includes, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or their combination. Each of the first to third gate electrodes G1, G2 and G3 may include a conductive metal oxide or a conductive metal oxynitride, etc., and/or may also include oxidized forms of the materials described above.

The gate spacer 112 extends in the second horizontal direction DR2 along a sidewall of each of the first to third gate electrodes G1, G2 and G3 on the field insulating layer 105. The gate spacer 112 extends in the second horizontal direction DR2 along the sidewall of each of the first to third gate electrodes G1, G2 and G3 on the uppermost one of the plurality of nanosheets NW.

The gate insulating layer 111 is disposed between each of the first to third gate electrodes G1, G2 and G3 and the plurality of nanosheets NW. The gate insulating layer 111 is disposed between each of the first to third gate electrodes G1, G2 and G3 and the gate spacer 112. The gate insulating layer 111 is disposed between each of the first to third gate electrodes G1, G2 and G3 and each of the first and second source/drain regions 121 and 122. The gate insulating layer 111 is disposed between each of the first to third gate electrodes G1, G2 and G3 and each of the first to fourth active patterns F1, F2, F3 and F4. The gate insulating layer 111 is disposed between each of the first to third gate electrodes G1, G2 and G3 and the field insulating layer 105.

The gate insulating layer 111 includes at least one of silicon oxide, silicon oxynitride, silicon nitride, or a high dielectric constant material that has a dielectric constant greater than that of silicon oxide. The high dielectric constant material includes one or more of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some embodiments includes a negative capacitance (NC) FET based on a negative capacitor. For example, the gate insulating layer 111 includes a ferroelectric material layer that has ferroelectric characteristics, and a paraelectric material layer that has paraelectric characteristics.

The ferroelectric material layer has a negative capacitance, and the paraelectric material layer has a positive capacitance. For example, when two or more capacitors are connected in series, and the capacitance of each capacitor has a positive value, the total capacitance lower than the capacitance of each individual capacitor. On the other hand, when at least one of capacitances of two or more capacitors connected in series has a negative value, the total capacitance may have a positive value and be greater than an absolute value of each individual capacitance.

When a negative capacitance ferroelectric material layer and a positive capacitance paraelectric material layer are connected in series, the total capacitance value of the series-connected ferroelectric material layer and paraelectric material layer is increased. Based on the increased total capacitance value, a transistor that includes a ferroelectric material layer has a subthreshold swing (SS) less than 60 mV/decade at a room temperature.

The ferroelectric material layer has ferroelectric characteristics. The ferroelectric material layer includes at least one of, for example, hafnium oxide, hafnium zirconium oxide, barium strontium titanium oxide, barium titanium oxide, or lead zirconium titanium oxide. For example, hafnium zirconium oxide may be hafnium oxide doped with zirconium (Zr). For example, hafnium zirconium oxide may be a compound of hafnium (Hf), zirconium (Zr) and oxygen (O).

The ferroelectric material layer further includes a doped dopant. For example, the dopant includes at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). The type of dopant in the ferroelectric material layer can vary depending on the ferroelectric material of the ferroelectric material layer.

When the ferroelectric material layer includes hafnium oxide, the dopant in the ferroelectric material layer includes at least one of gadolinium (Gd), silicon (Si), zirconium (Zr), aluminum (Al), or yttrium (Y).

When the dopant is aluminum (Al), the ferroelectric material layer includes aluminum at a concentration of 3 at % (atomic %) to 8 at %. In this case, a ratio of the dopant is a ratio of the aluminum to a sum of the hafnium and aluminum.

When the dopant is silicon (Si), the ferroelectric material layer includes silicon at a concentration of 2 at % to 10 at %. When the dopant is yttrium (Y), the ferroelectric material layer includes yttrium at a concentration of 2 at % to 10 at %. When the dopant is gadolinium (Gd), the ferroelectric material layer includes gadolinium at a concentration of 1 at % to 7 at %. When the dopant is zirconium (Zr), the ferroelectric material layer includes zirconium at a concentration of 50 at % to 80 at %.

The paraelectric material layer has paraelectric characteristics. The paraelectric material layer includes at least one of, for example, silicon oxide or a metal oxide that has a high dielectric constant. The metal oxide in the paraelectric material layer includes at least one of, for example, hafnium oxide, zirconium oxide, or aluminum oxide, but is not limited thereto.

The ferroelectric material layer and the paraelectric material layer may include the same material. Although the ferroelectric material layer has ferroelectric characteristics, the paraelectric material layer does not have ferroelectric characteristics. For example, when the ferroelectric material layer and the paraelectric material layer include hafnium oxide, a crystal structure of hafnium oxide in the ferroelectric material layer differs from that of hafnium oxide in the paraelectric material layer.

The ferroelectric material layer has a thickness sufficient to support ferroelectric characteristics. The thickness of the ferroelectric material layer is, for example, from 0.5 nm to 10 nm, but is not limited thereto. Since a threshold thickness for ferroelectric characteristics may vary depending on each ferroelectric material, the thickness of the ferroelectric material layer may vary depending on the ferroelectric material.

For example, the gate insulating layer 111 includes one ferroelectric material layer. For example, the gate insulating layer 111 includes a plurality of ferroelectric material layers spaced apart from each other. The gate insulating layer 111 may have a stacked layer structure in which a plurality of ferroelectric material layers and a plurality of paraelectric material layers are alternately stacked.

The capping pattern 113 is disposed on the first to third gate electrodes G1, G2 and G3, respectively. For example, an upper surface of the capping pattern 113 is coplanar with an upper surface of the second interlayer insulating layer 140. The capping pattern 113 includes at least one of, for example, silicon nitride (SiN), silicon oxynitride (SiON), silicon oxide (SiO₂), silicon carbonitride (SiCN), silicon oxycarbonitride (SiOCN), or their combination.

The first source/drain region 121 is disposed on at least one side of each of the first to third gate electrodes G1, G2 and G3 on each of the first and second active patterns F1 and F2. The second source/drain region 122 is disposed on at least one side of each of the first to third gate electrodes G1, G2 and G3 on each of the third and fourth active patterns F3 and F4.

Each of the first and second source/drain regions 121 and 122 is in contact with the plurality of nanosheets NW. Although FIG. 2 shows that the upper surface of each of the first and second source/drain regions 121 and 122 protrudes higher than that of the uppermost one of the plurality of nanosheets NW, embodiments of the present disclosure are not limited thereto.

In addition, although FIG. 4 shows that the first source/drain region 121 disposed on the first active pattern F1 and the first source/drain region 121 disposed on the second active pattern F2 are spaced apart from each other, embodiments of the present disclosure are not limited thereto. In some embodiments, the first source/drain region 121 disposed on the first active pattern F1 and the first source/drain region 121 disposed on the second active pattern F2 have a merged shape.

The first interlayer insulating layer 130 is disposed on the field insulating layer 105. The first interlayer insulating layer 130 surrounds a sidewall of a lower portion of each of the first and second source/drain regions 121 and 122. The upper surface of each of the first and second source/drain regions 121 and 122 is higher than that of the first interlayer insulating layer 130.

The first interlayer insulating layer 130 includes at least one of, for example, silicon oxide, silicon nitride, silicon oxycarbide, silicon oxynitride, silicon oxycarbonitride, or a low dielectric constant material. For example, the low dielectric constant material includes, for example, at least one of Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SiLK, Amorphous Fluorinated Carbon, silica aerogels, silica xerogels, mesoporous silica or their combination, but embodiments of the present disclosure are not limited thereto.

The second interlayer insulating layer 140 is disposed on the first interlayer insulating layer 130. The second interlayer insulating layer 140 surrounds the sidewall of an upper portion of each of the first and second source/drain regions 121 and 122. The upper surface of each of the first and second source/drain regions 121 and 122 is lower than that of the second interlayer insulating layer 140. The second interlayer insulating layer 140 surrounds the sidewall of each of the first to third gate electrodes G1, G2, and G3. The second interlayer insulating layer 140 includes the same material as that of the first interlayer insulating layer 130, but embodiments of the present disclosure are not limited thereto.

The first etch stop layer 125 is disposed between the field insulating layer 105 and the first interlayer insulating layer 130. The first etch stop layer 125 is disposed along a surface of each of the first and second source/drain regions 121 and 122. For example, the first etch stop layer 125 is disposed between each of the first and second source/drain regions 121 and 122 and the first interlayer insulating layer 130. In addition, the first etch stop layer 125 is disposed between each of the first and second source/drain regions 121 and 122 and the second interlayer insulating layer 140.

However, the first etch stop layer 125 is not disposed between the first source/drain contact 150 and the first source/drain region 121 or between the second source/drain contact 160 and the second source/drain region 122. The first etch stop layer 125 includes at least one of, for example, silicon oxide, silicon nitride, silicon oxynitride, or a low dielectric constant material.

The first source/drain contact 150 penetrates through the second interlayer insulating layer 140 in the vertical direction DR3 and is electrically connected to the first source/drain region 121. For example, the first source/drain contact 150 extends to the upper surface of the first interlayer insulating layer 130. For example, the first source/drain contact 150 is disposed on the first source/drain region 121 between the second gate electrode G2 and the third gate electrode G3. For example, the first source/drain contact 150 is electrically connected to the first source/drain region 121 disposed on the first active pattern F1 and the first source/drain region 121 disposed on the second active pattern F2.

The first source/drain contact 150 surrounds the sidewall of an upper portion of the first source/drain region 121. A portion of the first source/drain contact 150 is disposed between the first source/drain region 121 and the second interlayer insulating layer 140. Further, another portion of the first source/drain contact 150 is disposed between the first source/drain region 121 disposed on the first active pattern F1 and the first source/drain region 121 disposed on the second active pattern F2.

The first source/drain contact 150 is in contact with each of the gate spacer 112 and the capping pattern 113. A width W1 of a lower surface of the first source/drain contact 150 in the second horizontal direction DR2 is greater than that of the upper surface of the first source/drain contact 150 in the second horizontal direction DR2.

The first source/drain contact 150 includes a first portion 150_1, a second portion 150_2, a first skirt S1, and a second skirt S2. The first portion 150_1 of the first source/drain contact 150 is disposed on the first source/drain region 121. The second portion 150_2 of the first source/drain contact 150 is disposed on the first portion 150_1 of the first source/drain contact 150.

The first portion 150_1 of the first source/drain contact 150 includes a first sidewall 150_1s1 and a second sidewall 150_1s2 that opposes the first sidewall 150_1s1 in the second horizontal direction DR2. The second portion 150_2 of the first source/drain contact 150 includes a first sidewall 150_2s1 and a second sidewall 150_2s2 that opposes the first sidewall 150_2s1 in the second horizontal direction DR2.

The first sidewall 150_1s1 of the first portion 150_1 of the first source/drain contact 150 has is continuous with the first sidewall 150_2s1 of the second portion 150_2 of the first source/drain contact 150. The second sidewall 150_1s2 of the first portion 150_1 of the first source/drain contact 150 is continuous with the second sidewall 150_2s2 of the second portion 150_2 of the first source/drain contact 150.

The skirts S1 and S2 protrude from a lower sidewall of the first source/drain contact 150 toward the second interlayer insulating layer 140 in a horizontal direction. In detail, the first skirt S1 protrudes in the second direction DR2 from the first sidewall 150_1s1 of the first portion 150_1 of the first source/drain contact 150 toward the second interlayer insulating layer 140. The second skirt S2 protrudes in a direction opposite to the second direction DR2 from the second sidewall 150_1s2 of the first portion 150_1 of the first source/drain contact 150 toward the second interlayer insulating layer 140.

The first skirt S1 and the second skirt S2 oppose each other in the second horizontal direction DR2. Each of the first skirt S1 and the second skirt S2 are in contact with the upper surface of the first interlayer insulating layer 130. A width W1 in the second horizontal direction DR2 between a sidewall of the first skirt S1 and a sidewall of the second skirt S2 increases toward the first interlayer insulating layer 130.

A width of a lower surface of the first portion 150_1 of the first source/drain contact 150 is greater than a width W2 of a lower surface of the second portion 150_2 of the first source/drain contact 150. In addition, a width W1 in the second horizontal direction DR2 between the lowermost portion of the sidewall of the first skirt S1 and the lowermost portion of the sidewall of the second skirt S2 is greater than the width W2 of the lower surface of the second portion 150_2 of the first source/drain contact 150.

The first source/drain contact 150 includes a first barrier layer 151 and a first filling layer 152. The first barrier layer 151 forms a sidewall and a bottom surface of the first source/drain contact 150. The first barrier layer 151 is in contact with each of the gate spacer 112 and the capping pattern 113. The first filling layer 152 is disposed on the first barrier layer 151. For example, the first barrier layer 151 is disposed between the first interlayer insulating layer 130 and the first filling layer 152, between the second interlayer insulating layer 140 and the first filling layer 152, and between the first source/drain region 121 and the first filling layer 152.

An upper surface of the first source/drain contact 150 is coplanar with the upper surface of the second interlayer insulating layer 140. For example, the uppermost surface of the first barrier layer 151 and the upper surface of the first filling layer 152 are coplanar with the second interlayer insulating layer 140.

The first barrier layer 151 includes at least one of, for example, tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), zirconium (Zr), zirconium nitride (ZrN), vanadium (V), vanadium nitride (VN), niobium (Nb), niobium nitride (NbN), platinum (Pt), iridium (Ir), or rhodium (Rh), but embodiments of the present disclosure are not limited thereto.

The first filling layer 152 includes at least one of, for example, aluminum (Al), copper (Cu), tungsten (W), cobalt (Co), ruthenium (Ru), or molybdenum (Mo), but embodiments of the present disclosure are not limited thereto.

The second source/drain contact 160 is disposed on the second source/drain region 122 between the first gate electrode G1 and the second gate electrode G2. For example, the second source/drain contact 160 is electrically connected to the second source/drain region 122 disposed on the third active pattern F3 and the second source/drain region 122 disposed on the fourth active pattern 4. The second source/drain contact 160 has a structure similar to that of the first source/drain contact 150. Therefore, a detailed description of the second source/drain contact 160 will be omitted.

The silicide layer 155 is disposed between the first source/drain region 121 and the first source/drain contact 150. The silicide layer 155 is disposed along a contour of an upper surface of the first source/drain region 121 inside the second interlayer insulating layer 140. For example, a portion of the first source/drain contact 150 is disposed between the silicide layer 155 and the second interlayer insulating layer 140 in the second direction DR2. The silicide layer 155 includes, for example, a metal silicide material.

The gate contact 170 penetrates through the capping pattern 113 in the vertical direction DR3 and is electrically connected to at least one of the first to third gate electrodes G1, G2 and G3. The gate contact 170 includes a second barrier layer 171 and a second filling layer 172. The second barrier layer 171 forms a sidewall and a bottom surface of the gate contact 170. The second filling layer 172 is disposed on the second barrier layer 171 and fills a space formed by the second barrier layer 171. An upper surface of the gate contact 170 is coplanar with the upper surface of the capping pattern 113, but embodiments of the present disclosure are not limited thereto.

The second barrier layer 171 includes at least one of, for example, tantalum (Ta), tantalum nitride, titanium (Ti), titanium nitride (TiN), ruthenium (Ru), cobalt (Co), nickel (Ni), nickel boron (NiB), tungsten (W), tungsten nitride (WN), zirconium (Zr), zirconium nitride (ZrN), vanadium (V), vanadium nitride (VN), niobium (Nb), niobium nitride (NbN), platinum (Pt), iridium (Ir), or rhodium (Rh), but embodiments of the present disclosure are not limited thereto.

The second filling layer 172 includes at least one of, for example, aluminum (Al), copper (Cu), tungsten (W), cobalt (Co), ruthenium (Ru), or molybdenum (Mo), but embodiments of the present disclosure are not limited thereto.

The second etch stop layer 180 is disposed on the second interlayer insulating layer 140 and the capping pattern 113. The second etch stop layer 180 covers a portion of an upper surface of each of the first source/drain contact 150, the second source/drain contact 160 and the gate contact 170. Although the second etch stop layer 180 is shown as being formed of a single layer in FIGS. 2 to 4, embodiments of the present disclosure are not limited thereto. In some embodiments, the second etch stop layer 180 has a multi-layer structure. The second etch stop layer 180 includes at least one of, for example, silicon oxide, silicon nitride, silicon oxynitride, or a low dielectric constant material.

The third interlayer insulating layer 190 is disposed on the second etch stop layer 180. The third interlayer insulating layer 190 includes at least one of, for example, silicon oxide, silicon nitride, silicon oxynitride, or a low dielectric constant material.

The first via V1 penetrates through the third interlayer insulating layer 190 and the second etch stop layer 180 in the vertical direction DR3 and is connected to the first source/drain contact 150. Although FIG. 4 shows that the first via V1 has a single layer, this is for convenience of description, and embodiments of the present disclosure are not limited thereto. In an embodiment, the first via V1 has a multi-layer structure. The first via V1 includes a conductive material.

The second via V2 penetrates through the third interlayer insulating layer 190 and the second etch stop layer 180 in the vertical direction DR3 and is connected to the gate contact 170. Although FIG. 3 shows that the second via V2 has a single layer, this is for convenience of description, and embodiments of the present disclosure are not limited thereto. In an embodiment, the second via V2 has a multi-layer structure. The second via V2 includes a conductive material.

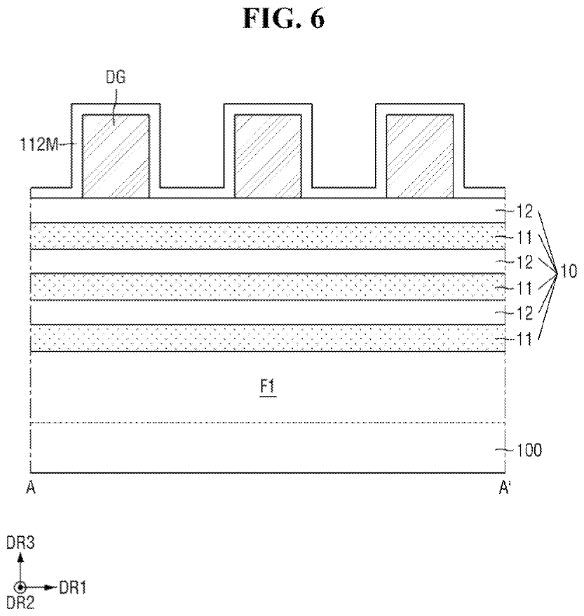

Hereinafter, a method of manufacturing a semiconductor device according to some embodiments of the present disclosure will be described with reference to FIGS. 6 to 34.

FIGS. 6 to 34 illustrate intermediate steps of a method of manufacturing a semiconductor device according to some embodiments of the present disclosure.

Referring to FIG. 6, in an embodiment, a stacked structure 10 that includes a first semiconductor layer 11 and a second semiconductor layer 12 that are alternately stacked is formed on a substrate 100. For example, the first semiconductor layer 11 is formed at a lowermost portion of the stacked structure 10, and the second semiconductor layer 12 is formed on an uppermost portion of the stacked structure 10, but embodiments of the present disclosure are not limited thereto. The first semiconductor layer 11 includes, for example, silicon germanium (SiGe). The second semiconductor layer 12 includes, for example, silicon (Si).

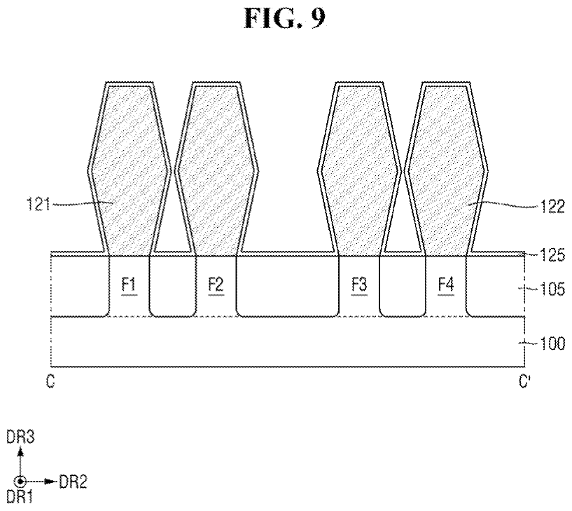

A portion of the stacked structure 10 and the substrate 100 is etched. First to fourth active patterns F1, F2, F3 and F4, shown in FIG. 9, are formed on the substrate 100 through an etching process. The first active pattern F1 is shown in FIG. 6. Each of the first to fourth active patterns F1, F2, F3 and F4 extends in the first horizontal direction DR1. A field insulating layer 105, shown in FIG. 9, is formed on the substrate 100 and surrounds sidewalls of the first to fourth active patterns F1, F2, F3 and F4.

A plurality of dummy gates DG are formed on the stacked structure 10. Each of the plurality of dummy gates DG extends in the second horizontal direction DR2. The respective dummy gates DG are spaced apart from each other in the first horizontal direction DR1. A spacer material layer 112M is formed that covers the stacked structure 10 and each of the plurality of dummy gates DG. For example, the spacer material layer 112M is conformally formed on the stacked structure 10 and each of the plurality of dummy gates DG.

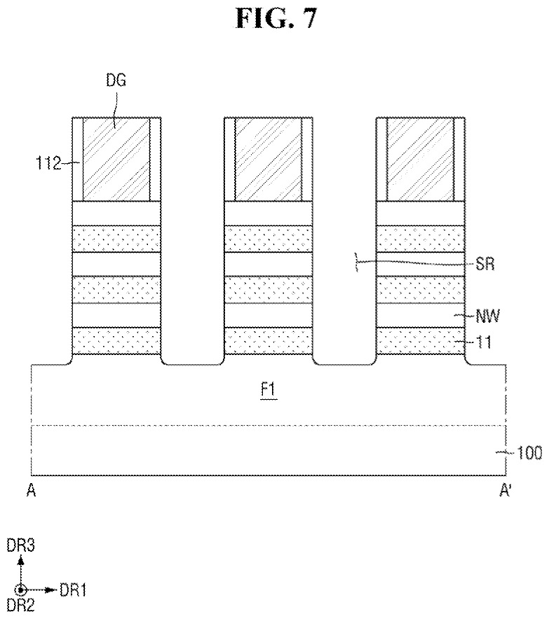

Referring to FIG. 7, in an embodiment, the stacked structure 10 is etched using the spacer material layer 112M and the plurality of dummy gates DG as masks to form a source/drain recess SR. The respective second semiconductor layers 12 separated by the source/drain recess SR form a plurality of nanosheets NW.

While the source/drain recess SR is being formed, the spacer material layer 112M on upper surfaces of the plurality of dummy gates DG is etched. Through this etching process, a gate spacer 112 is formed on sidewalls of the plurality of dummy gates DG. The source/drain recess SR extends in the third direction DR3 into the first active pattern F1.

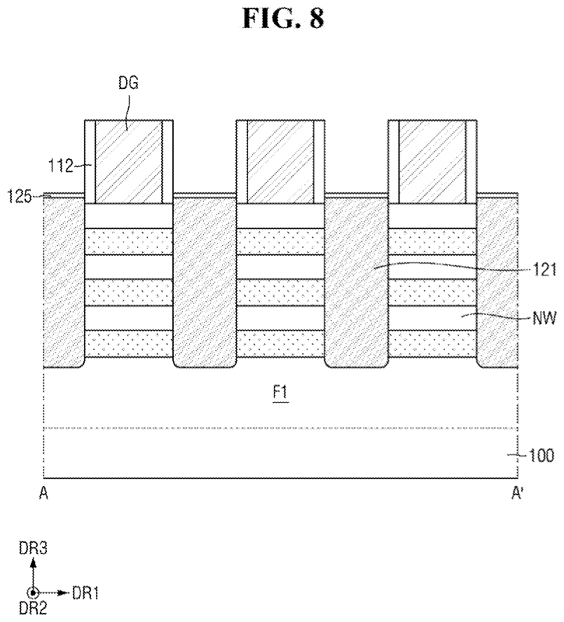

Referring to FIGS. 8 and 9, in an embodiment, a first source/drain region 121 and a second source/drain region 122 are formed in the source/drain recess SR. For example, the first source/drain region 121 is formed inside the source/drain recess SR on the first and second active patterns F1 and F2. In addition, the second source/drain region 122 is formed inside the source/drain recess SR on the third and fourth active patterns F3 and F4.

A first etch stop layer 125 is formed on a sidewall and an upper surface of the first source/drain region 121, a sidewall and an upper surface of the second source/drain region 122, and an upper surface of the field insulating layer 105. For example, first etch stop layer 125 is conformally formed on the first source/drain region 121, the second source/drain region 122 and the field insulating layer 105.

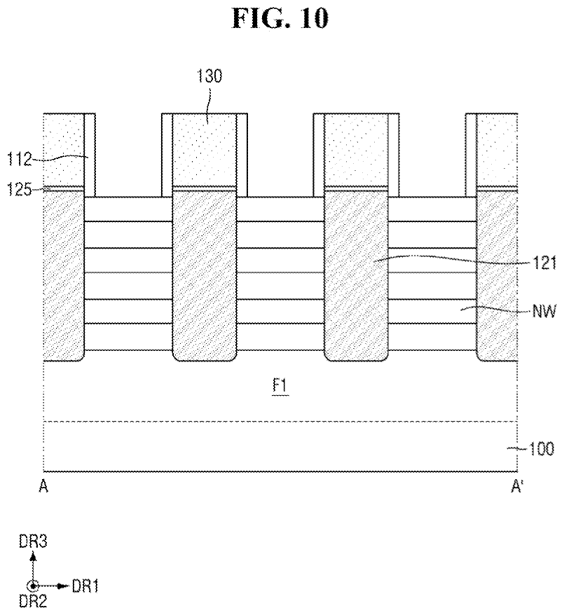

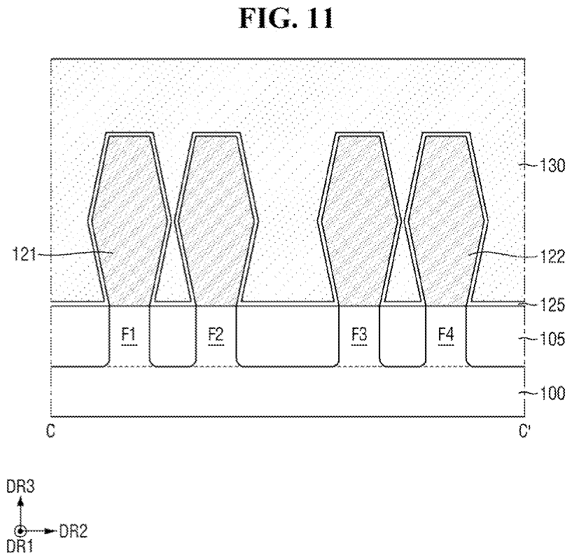

Referring to FIGS. 10 and 11, in an embodiment, a first interlayer insulating layer 130 is formed on the field insulating layer 105. The first interlayer insulating layer 130 covers the first source/drain region 121, the second source/drain region 122 and each of the plurality of dummy gates DG. The upper surfaces of the plurality of dummy gates DG are exposed through a planarization process. The plurality of dummy gates DG and the first semiconductor layer 11 are removed.

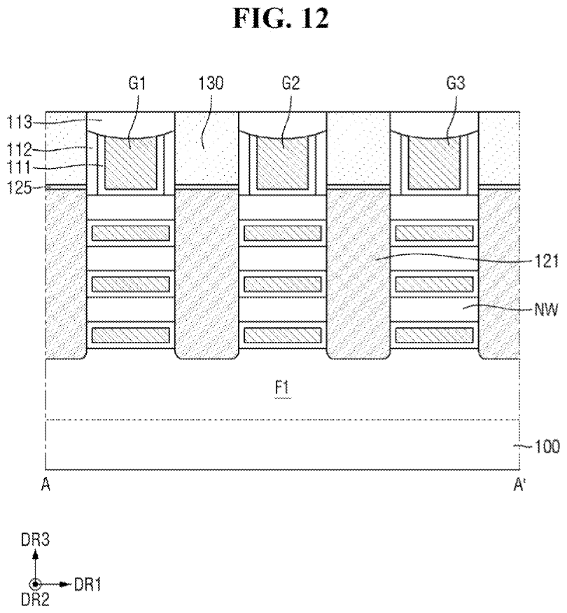

Referring to FIG. 12, in an embodiment, a gate insulating layer 111 and first to third gate electrodes G1, G2 and G3 are formed at locations from which the plurality of dummy gates DG and the first semiconductor layer 11 are removed. After an upper portion of each of the gate insulating layer 111, the gate spacer 112 and the first to third gate electrodes G1, G2 and G3 is etched, a capping pattern 113 that extends in the second horizontal direction DR2 is formed.

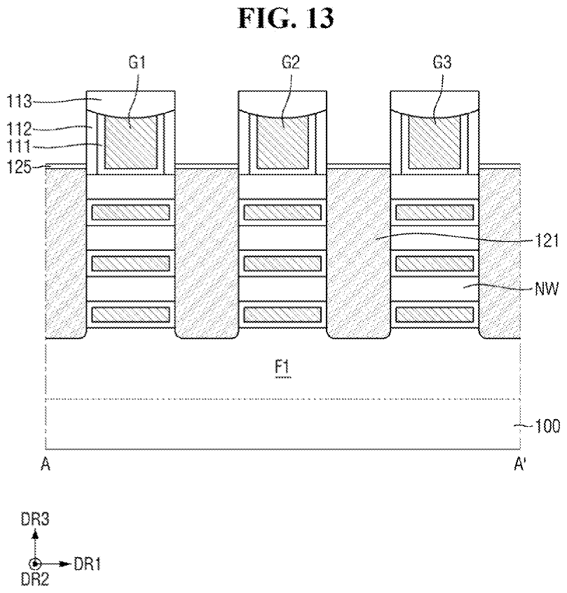

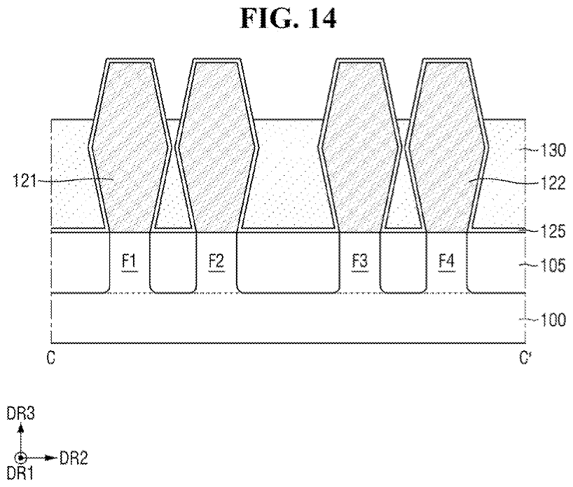

Referring to FIGS. 13 and 14, in an embodiment, a portion of the first interlayer insulating layer 130 is etched. Through this etching process, the first etch stop layer 125 formed on the first source/drain region 121 and the second source/drain region 122 is exposed. In addition, a portion of a sidewall of the gate spacer 112 formed on the first active pattern F1 and a sidewall of the capping pattern are exposed through the etching process. An upper surface of the etched first interlayer insulating layer 130 is formed lower than an upper surface of each of the first source/drain region 121 and an upper surface of the second source/drain region 122.

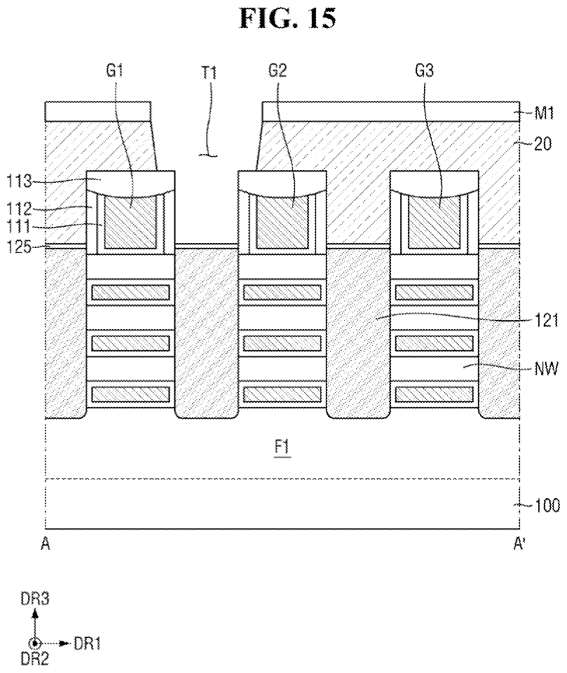

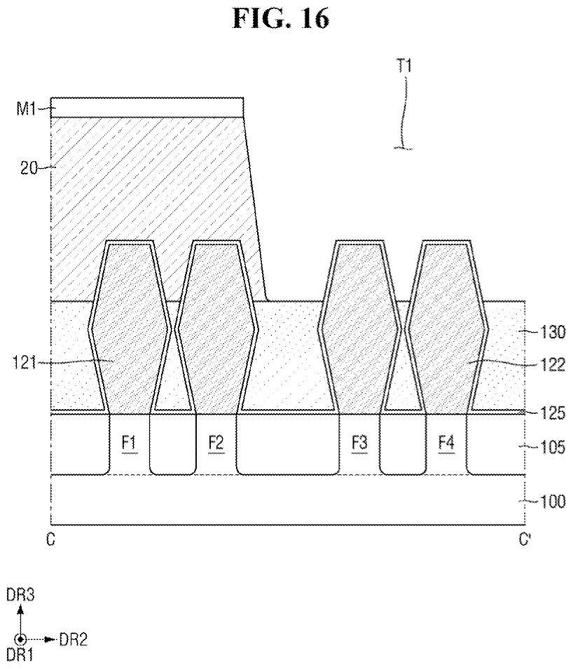

Referring to FIGS. 15 and 16, in an embodiment, a first passivation layer 20 is formed on the first interlayer insulating layer 130. The first passivation layer 20 covers the first etch stop layer 125, the gate spacer 112 and the capping pattern 113, which are exposed. The first passivation layer 20 includes, for example, SOH.

A first mask pattern M1 is formed on the first passivation layer 20. The first passivation layer 20 is etched using the first mask pattern M1 as a mask to form a first trench T1. For example, the first trench T1 is formed between the first gate electrode G1 and the second gate electrode G2 on the first active pattern F1. In addition, the first trench T1 is formed on the first insulating interlayer 130 on the third and fourth active patterns F3 and F4 between the second gate electrode G2 and the third gate electrode G3. As shown in FIG. 16, a lower sidewall of the first trench T1 corresponds to a sidewall of the first passivation layer 20, which is not etched, has a shape that corresponds to the second skirt S2 shown in FIG. 4.

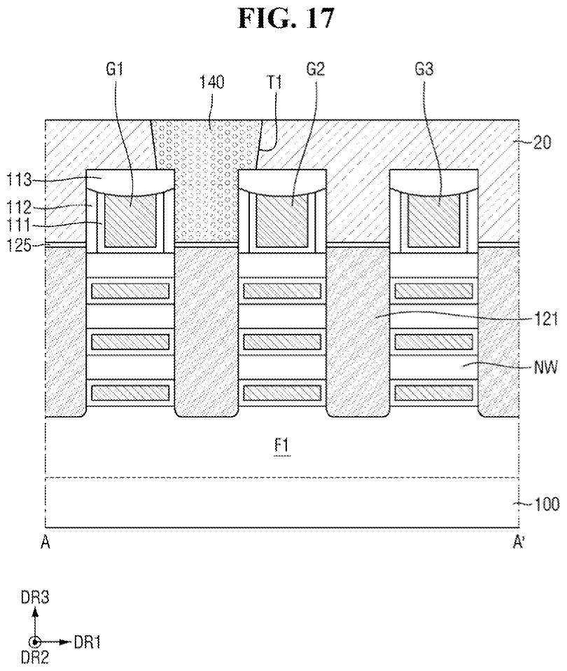

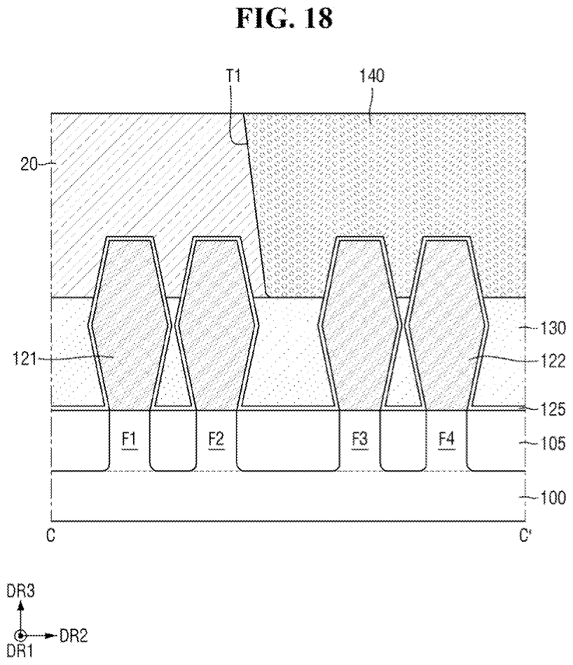

Referring to FIGS. 17 and 18, in an embodiment, a second interlayer insulating layer 140 is formed in the first trench T1. For example, the second interlayer insulating layer 140 completely fills the first trench T1. The first mask pattern M1 is removed.

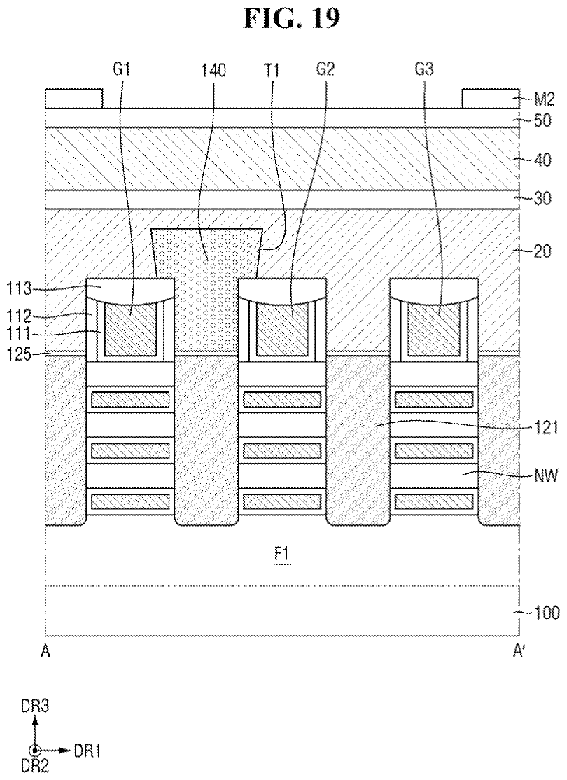

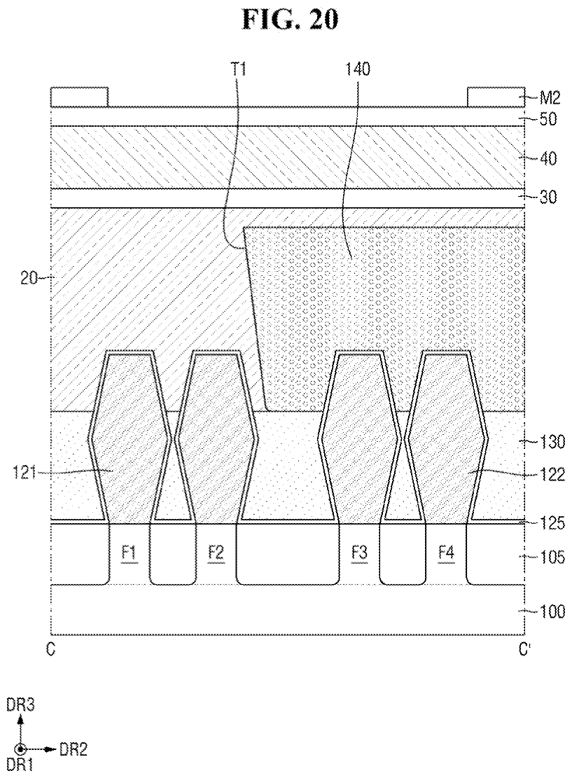

Referring to FIGS. 19 and 20, in an embodiment, the first passivation layer 20 covers an upper surface of the second interlayer insulating layer 140. A third etch stop layer 30, a second passivation layer 40 and a fourth etch stop layer 50 are sequentially formed.

Although FIGS. 19 and 20 show that each of the third etch stop layer 30 and the fourth etch stop layer 50 has a single layer, embodiments of the present disclosure are not limited thereto. In some embodiments, each of the third etch stop layer 30 and the fourth etch stop layer 50 has a multi-layer structure. Each of the third etch stop layer 30 and the fourth etch stop layer 50 includes at least one of, for example, silicon oxide, silicon nitride, silicon oxynitride, or a low dielectric constant material. The second passivation layer 40 includes, for example, SOH. A second mask pattern M2 is formed on the fourth etch stop layer 50.

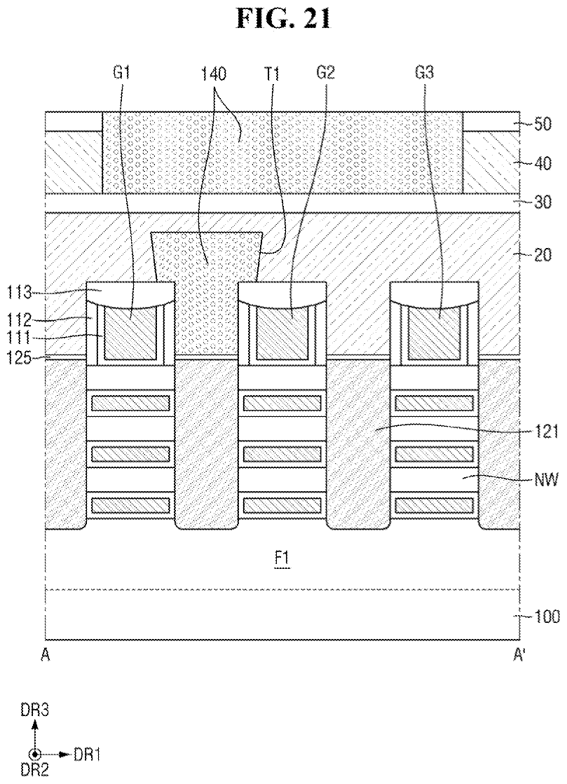

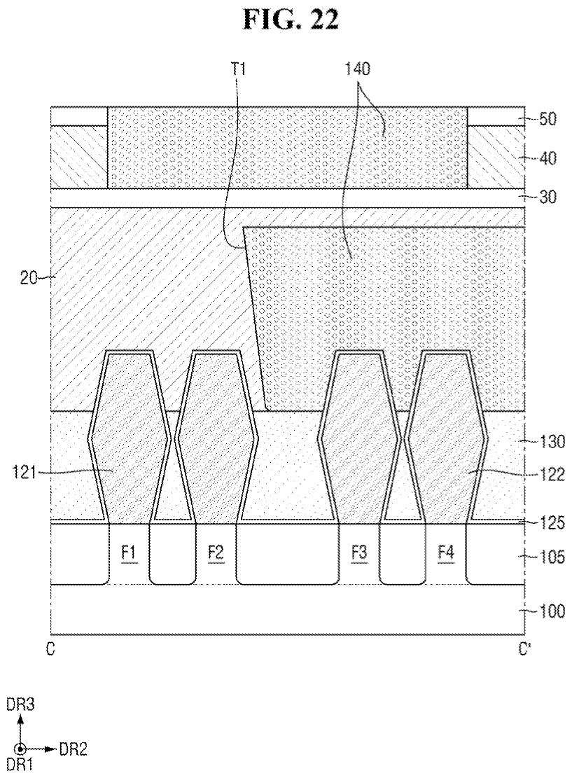

Referring to FIGS. 21 and 22, in an embodiment, the fourth etch stop layer 50 and the second passivation layer 40 are etched using the second mask pattern M2 as a mask. The second interlayer insulating layer 140 is additionally formed on locations where the fourth etch stop layer 50 and the second passivation layer 40 are etched. The additional second interlayer insulating layer 140 overlaps the second interlayer insulating layer 140 between the first gate electrode G1 and the second gate electrode G2 in the vertical direction DR3. Further, the additional second interlayer insulating layer 140 overlaps the first source/drain region 121 formed between the second gate electrode G2 and the third gate electrode G3 in the vertical direction DR3.

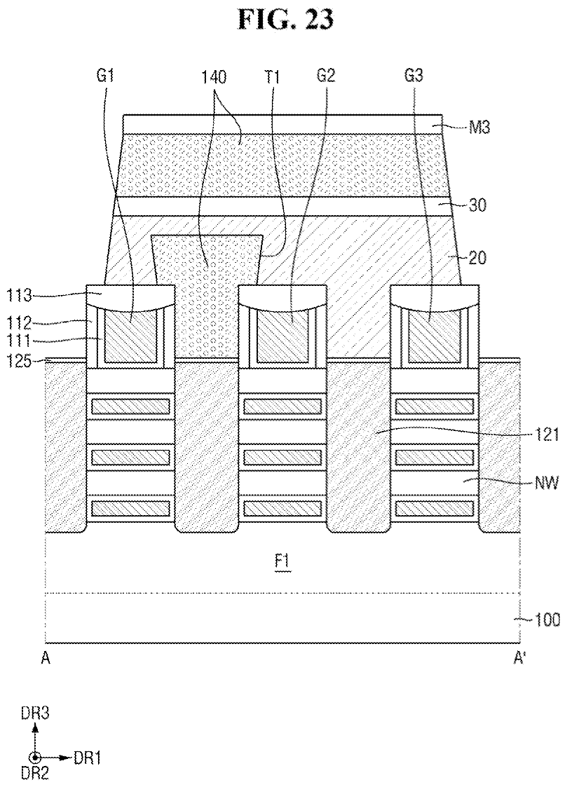

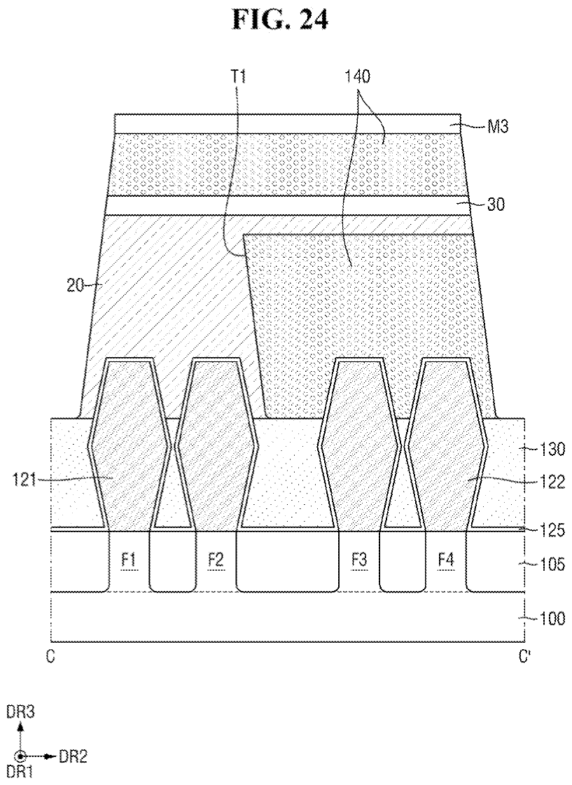

Referring to FIGS. 23 and 24, in an embodiment, a third mask pattern M3 is formed on the additional second interlayer insulating layer 140. The fourth etch stop layer 50, the second passivation layer 40, the third etch stop layer 30, the first passivation layer 20 and the second interlayer insulating layer 140 are etched using the third mask pattern M3 as a mask.

Through an etching process that uses the third mask pattern M3, the gate spacer 112 formed on one side of the first gate electrode G1 and the gate spacer 112 formed on one side of the third gate electrode G3 are exposed. In addition, the upper surface of the first interlayer insulating layer 130 is exposed through an etching process that uses the third mask pattern M3.

Through an etching process that uses the third mask pattern M3, a lower portion of the sidewall of the first passivation layer 20 adjacent to the first source/drain region 121 on the first active pattern F1 between the second gate electrode G2 and the third gate electrode G3 has a shape that corresponds to the first skirt S1 shown in FIG. 4.

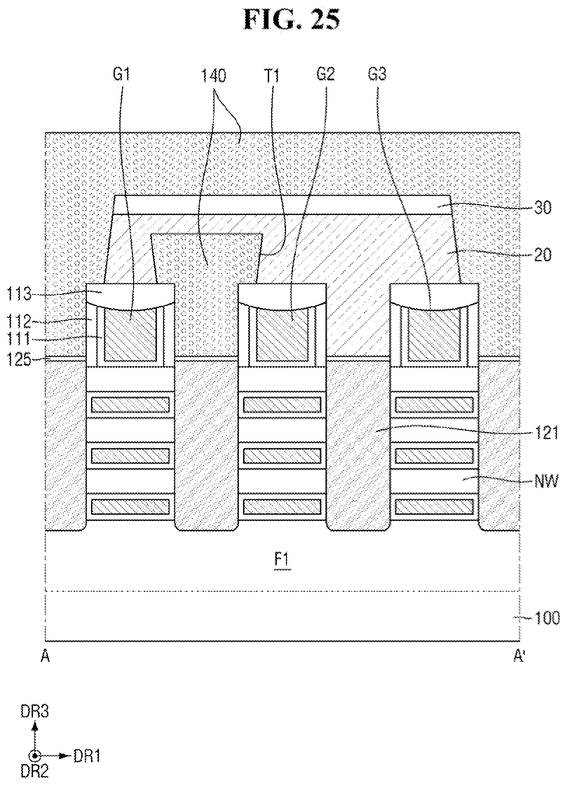

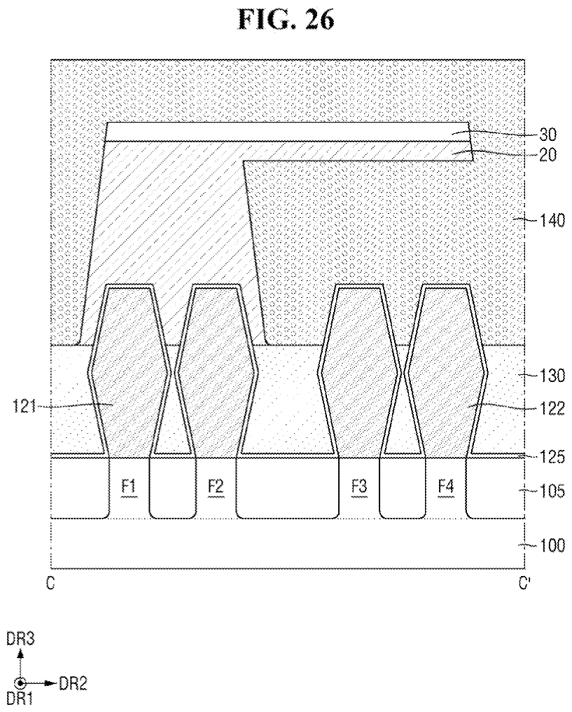

Referring to FIGS. 25 and 26, in an embodiment, after the third mask pattern M3 is removed, the second interlayer insulating layer 140 is additionally formed on the first interlayer insulating layer 130. The second interlayer insulating layer 140 covers the sidewall of the first passivation layer 20 and a sidewall of the third etch stop layer 30.

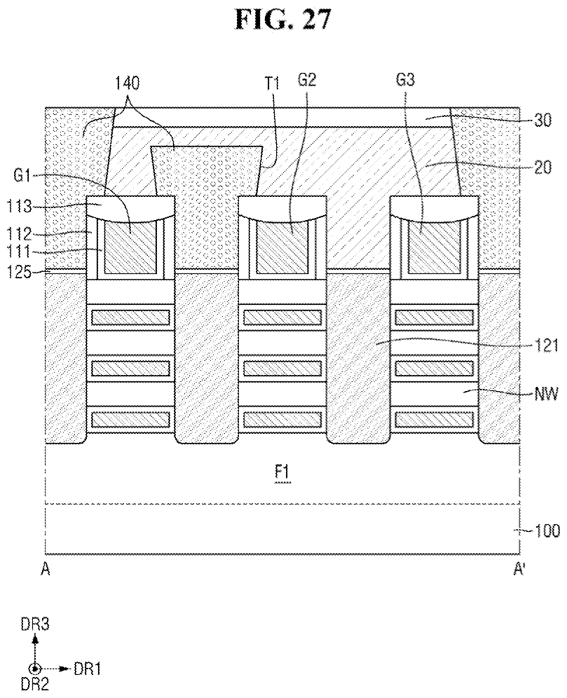

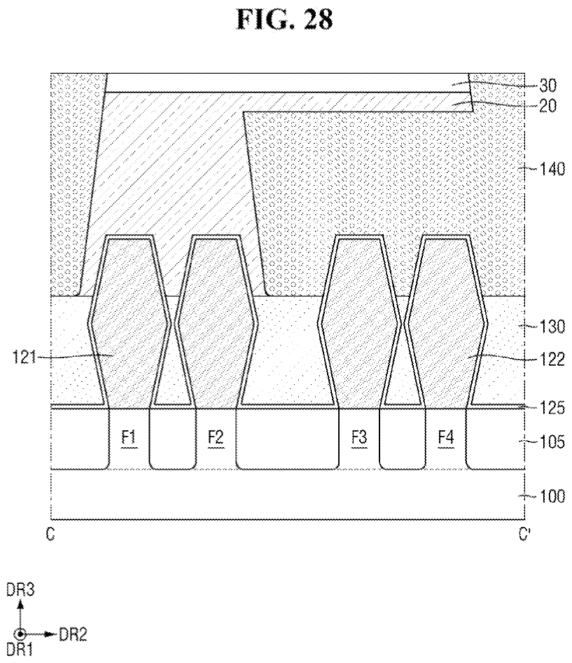

Referring to FIGS. 27 and 28, in an embodiment, an upper surface of the third etch stop layer 30 is exposed through a planarization process.

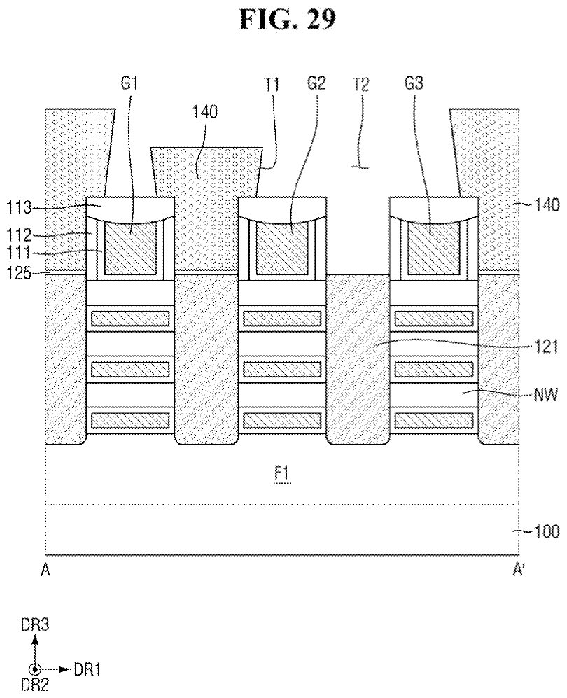

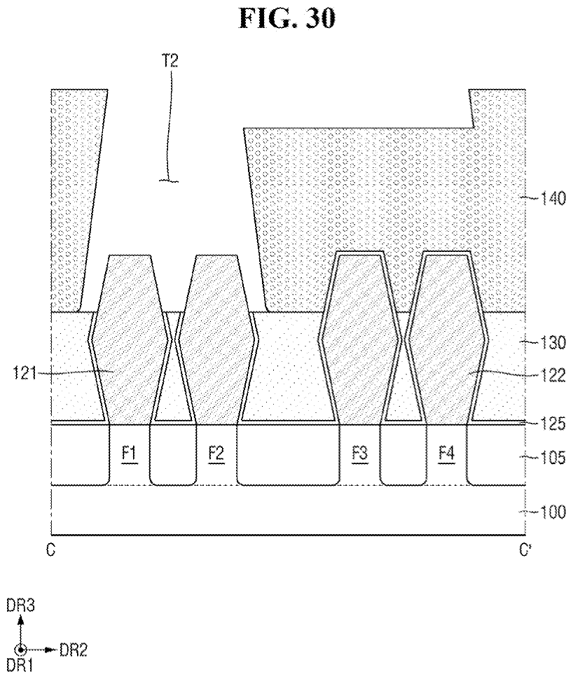

Referring to FIGS. 29 and 30, in an embodiment, the first passivation layer 20 and the third etch stop layer 30 are removed to form a second trench T2. The first etch stop layer 125 on the first source/drain region 121 between the second gate electrode G2 and the third gate electrode G3 is exposed by the second trench T2. The first etch stop layer 125 exposed to the second trench T2 is removed. As a result, the first source/drain region 121 is exposed between the second gate electrode G2 and the third gate electrode G3 by the second trench T2.

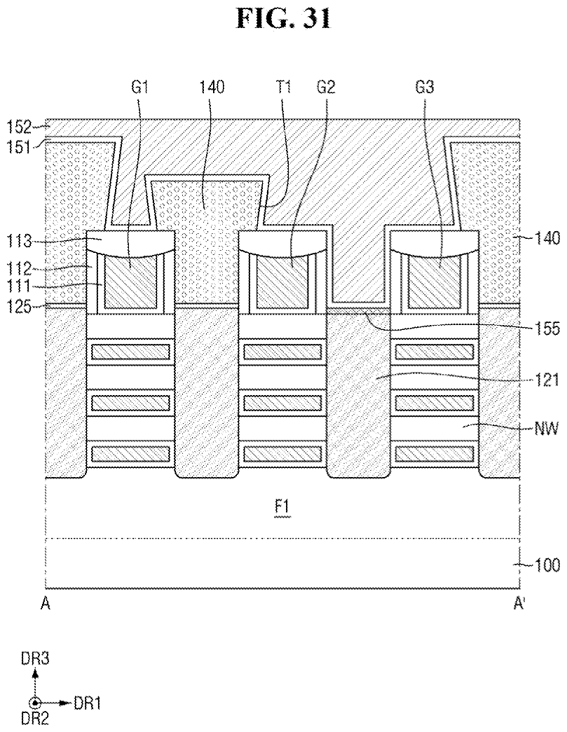

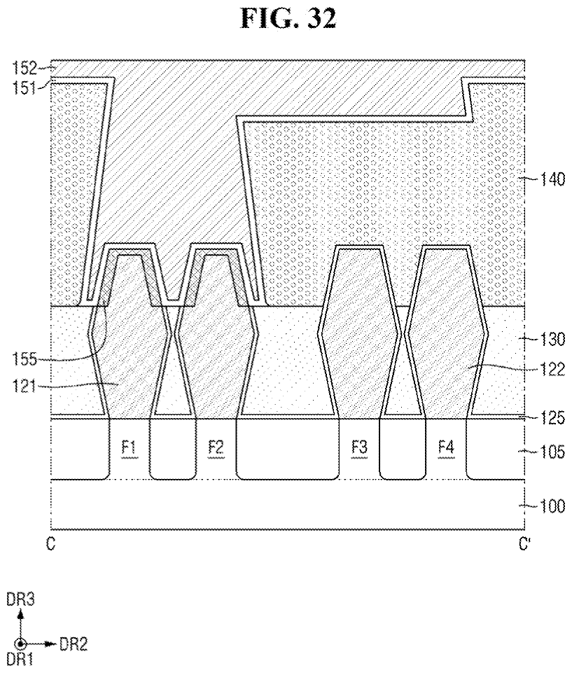

Referring to FIGS. 31 and 32, in an embodiment, a first barrier layer 151 is formed along a sidewall and a bottom surface of the second trench T2. For example, the first barrier layer 151 is conformally formed along the sidewall and the bottom surface of the second trench T2.

A silicide layer 155 is formed by heat-treating the first barrier layer 151. For example, the silicide layer 155 is formed between the first source/drain region 121 and the first barrier layer 151 on the first and second active patterns F1 and F2. A first filling layer 152 is formed on the first barrier layer 151 that fills the second trench T2.

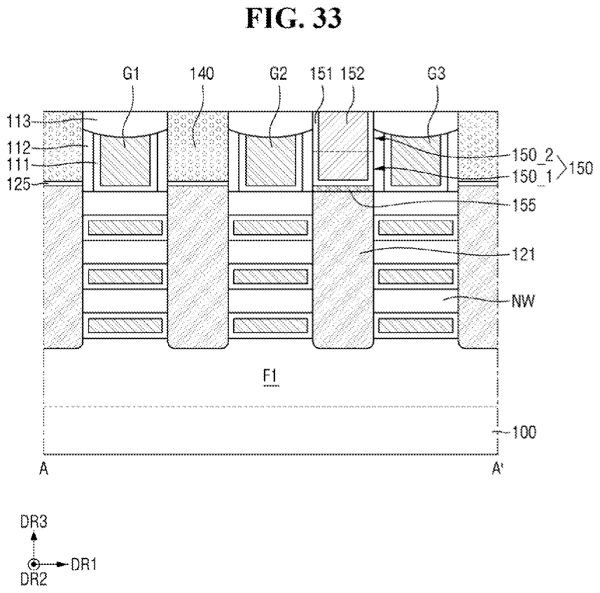

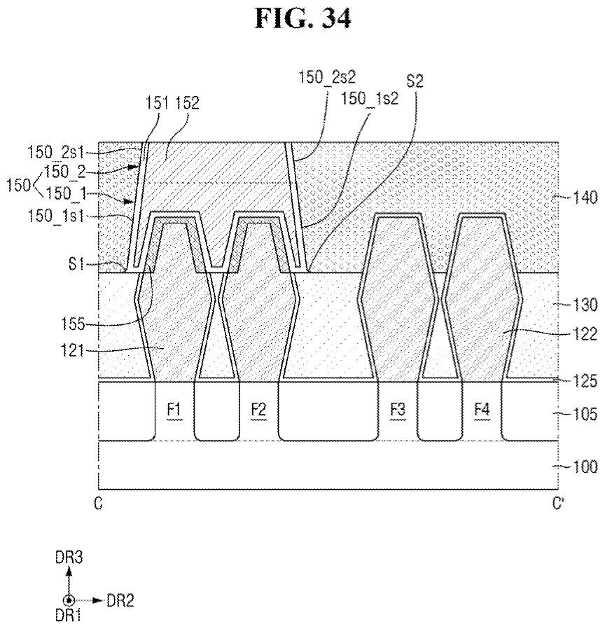

Referring to FIGS. 33 and 34, in an embodiment, an upper surface of the capping pattern 113 is exposed through a planarization process. Through the planarization process, a first source/drain contact 150 electrically connected with the first source/drain region 121 is formed between the second gate electrode G2 and the third gate electrode G3.

Referring to FIGS. 2 to 4, in an embodiment, a gate contact 170 is formed that penetrates through the capping pattern 113 on the first gate electrode G1 in the vertical direction DR3. A second etch stop layer 180 and a third interlayer insulating layer 190 are sequentially formed on the second interlayer insulating layer 140 and the capping pattern 113.

A first via V1 is formed that penetrates through the third interlayer insulating layer 190 and the second etch stop layer 180 in the vertical direction DR3 and is electrically connected to the first source/drain contact 150. Further, a second via V2 is formed that penetrates through the third interlayer insulating layer 190 and the second etch stop layer 180 in the vertical direction DR3 and is electrically connected to the gate contact 170. Through this manufacturing process, a semiconductor device shown in FIGS. 2 to 4 is manufactured.

In a semiconductor device and a method of manufacturing a semiconductor device according to some embodiments of the present disclosure, after the gate electrodes G1, G2 and G3 are formed, a passivation layer 20 is formed where the source/drain contact 150 will be formed in a subsequent process. The passivation layer 20 is removed, and then the source/drain contact 150 is formed. As a result, in a semiconductor device and a method of manufacturing a semiconductor device according to some embodiments of the present disclosure, the capping pattern 113 is prevented from being etched during the process of forming the source/drain contact 150, so that a short is prevented from occurring between the gate electrodes G1, G2 and G3 and the source/drain contact 150.

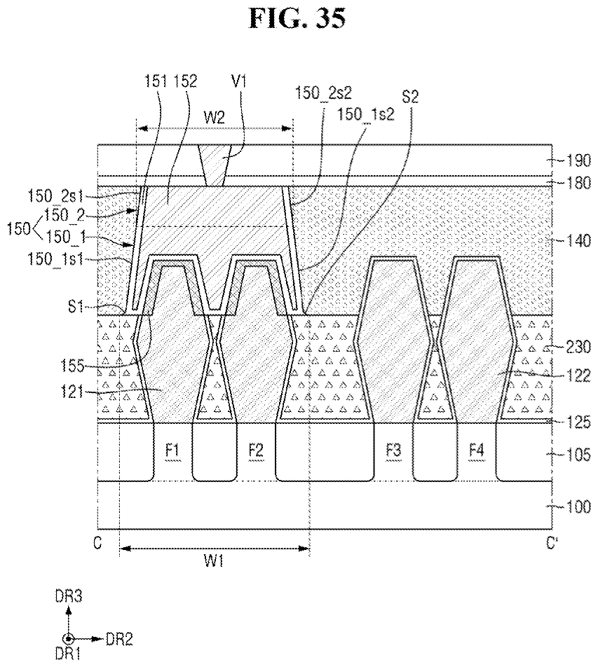

Hereinafter, a semiconductor device according to some embodiments of the present disclosure will be described with reference to FIG. 35. The following description will focus on differences from a semiconductor device shown in FIGS. 1 to 5.

FIG. 35 is a cross-sectional view of a semiconductor device according to some embodiments of the present disclosure.

Referring to FIG. 35, in a semiconductor device according to some embodiments of the present disclosure, a first interlayer insulating layer 230 and a second interlayer insulating layer 140 have different materials from each other. For example, the first interlayer insulating layer 230 includes silicon oxide, and the second interlayer insulating layer 140 includes at least one of silicon nitride, silicon oxycarbide, silicon oxynitride, silicon oxycarbonitride, or a low dielectric constant material.

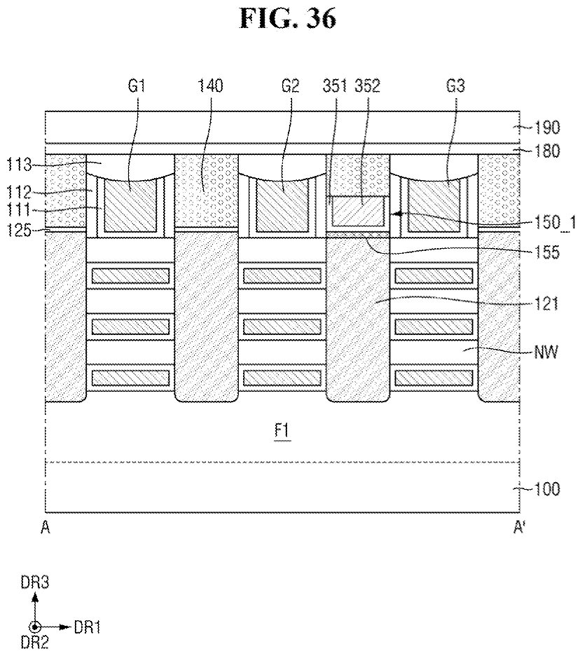

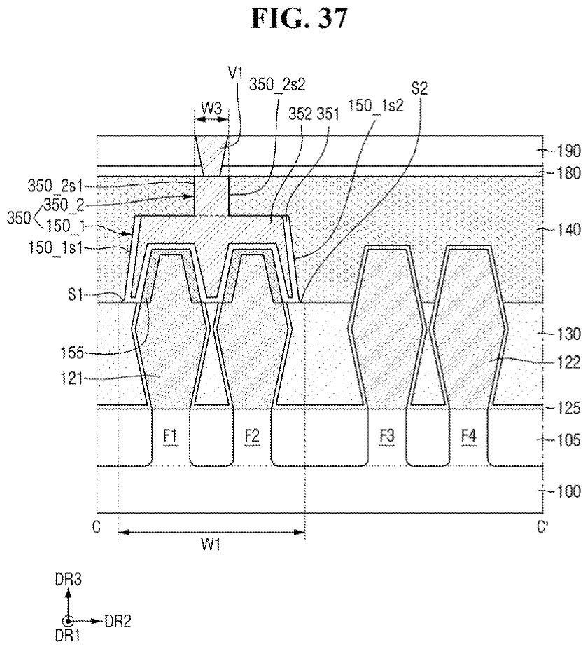

Hereinafter, a semiconductor device according to some embodiments of the present disclosure will be described with reference to FIGS. 36 and 37. The following description will focus on differences from a semiconductor device shown in FIGS. 1 to 5.

FIGS. 36 and 37 are cross-sectional views of a semiconductor device according to some embodiments of the present disclosure.

Referring to FIGS. 36 and 37, a semiconductor device according to some embodiments of the present disclosure includes a portion in which a first source/drain contact 350 protrudes in the vertical direction DR3. For example, the first source/drain contact 350 includes a first portion 150_1 disposed on the first source/drain region 121 and a second portion 350_2 disposed on the first portion 150_1.

A width in the second horizontal direction DR2 of an upper surface of the first portion 150_1 of the first source/drain contact 350 is greater than a width W3 in the second horizontal direction DR2 of a lower surface of the second portion 350_2 of the first source/drain contact 350. A portion of the upper surface of the first portion 150_1 of the first source/drain contact 350 is in contact with the second interlayer insulating layer 140.

A first sidewall 150_1s1 of the first portion 150_1 of the first source/drain contact 350 and a first sidewall 350_2s1 of the second portion 350_2 of the first source/drain contact 350 are discontinuous. In addition, a second sidewall 150_1s2 of the first portion 150_1 of the first source/drain contact 350 and a second sidewall 350_2s2 of the second portion 350_2 of the first source/drain contact 350 are discontinuous.

The first source/drain contact 350 includes a first barrier layer 351 and a first filling layer 352. The first barrier layer 351 forms a sidewall and a bottom surface of the first portion 150_1 of the first source/drain contact 350. The first filling layer 352 is disposed on the first barrier layer 351 and fills a space formed by the first barrier layer 351. An upper surface of the first filling layer 352 disposed in the first portion 150_1 of the first source/drain contact 350 is in contact with the second interlayer insulating layer 140. A sidewall of the first filling layer 352 disposed in the second portion 350_2 of the first source/drain contact 350 is in contact with the second interlayer insulating layer 140.

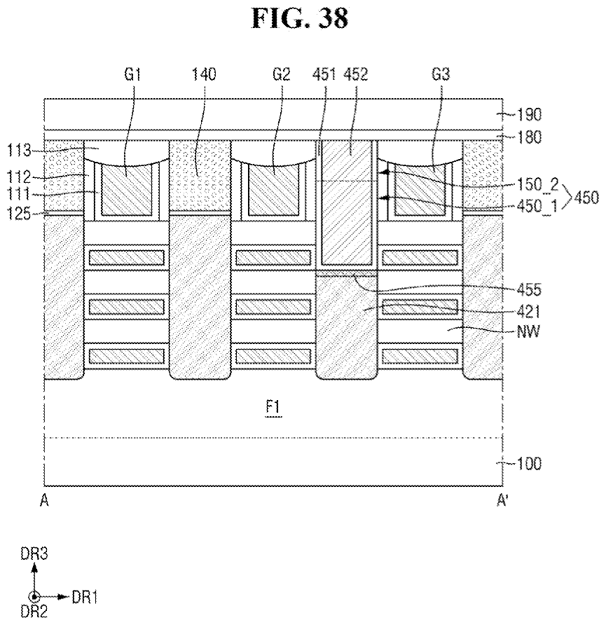

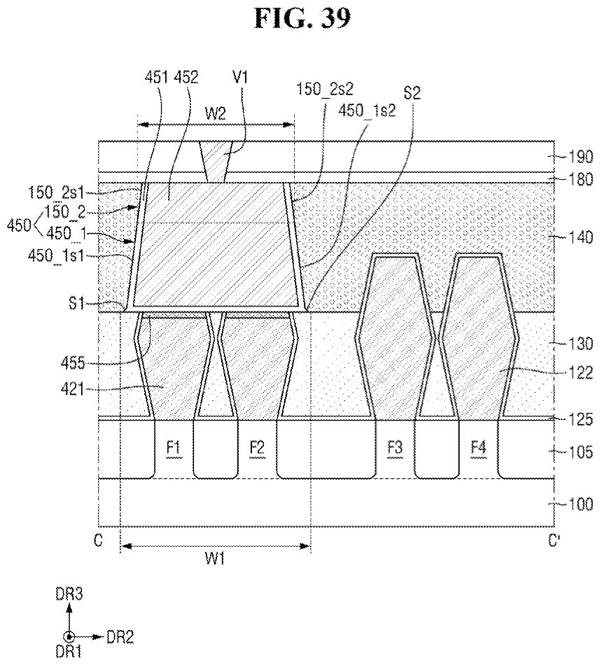

Hereinafter, a semiconductor device according to some embodiments of the present disclosure will be described with reference to FIGS. 38 and 39. The following description will focus on differences from a semiconductor device shown in FIGS. 1 to 5.

FIGS. 38 and 39 are cross-sectional views of a semiconductor device according to some embodiments of the present disclosure.

Referring to FIGS. 38 and 39, in a semiconductor device according to some embodiments of the present disclosure, a first source/drain region 421 is not disposed inside a first source/drain contact 450. For example, the first source/drain region 421 does not extend up into the first source/drain contact 450. For example, an upper surface of the first source/drain region 421 is disposed below the first source/drain contact 450 and is lower than that of the first interlayer insulating layer 130.

The first source/drain contact 450 includes a first portion 450_1 disposed on the first source/drain region 421 and a second portion 150_2 disposed on the first portion 450_1. A first sidewall 450_1s1 of the first portion 450_1 of the first source/drain contact 450 is continuous with a first sidewall 150_2s1 of the second portion 150_2 of the first source/drain contact 450. In addition, a second sidewall 450_1s2 of the first portion 450_1 of the first source/drain contact 450 is continuous with a second sidewall 150_2s2 of the second portion 150_2 of the first source/drain contact 450.

The first source/drain contact 450 includes a first barrier layer 451 and a first filling layer 452. The first barrier layer 451 forms a sidewall and a bottom surface of the first source/drain contact 450. The first filling layer 452 is disposed on the first barrier layer 451 and fills a space formed by the first barrier layer 451.

A silicide layer 455 is disposed between the first source/drain contact 450 and the first source/drain region 421. A lower surface of the silicide layer 455 is lower than the upper surface of the first interlayer insulating layer 130. The first etch stop layer 125 is disposed between the first interlayer insulating layer 130 and the silicide layer 455.

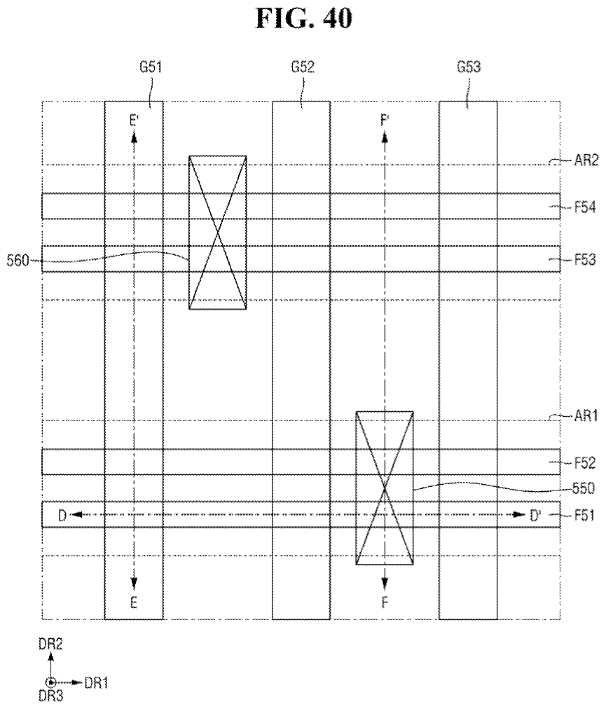

Hereinafter, a semiconductor device according to some embodiments of the present disclosure will be described with reference to FIGS. 40 to 43. The following description will focus on differences from a semiconductor device shown in FIGS. 1 to 5.

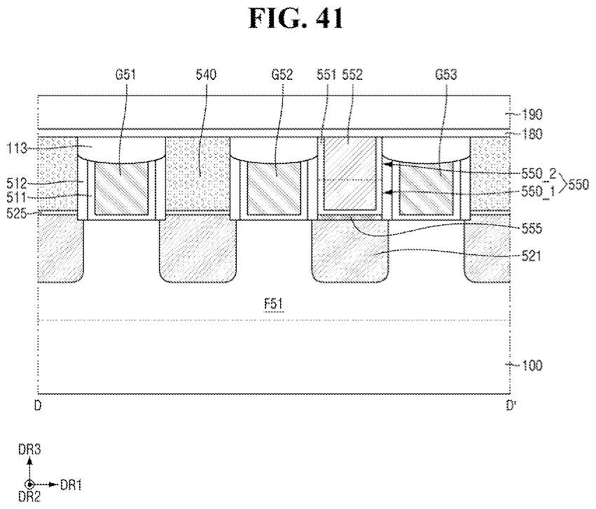

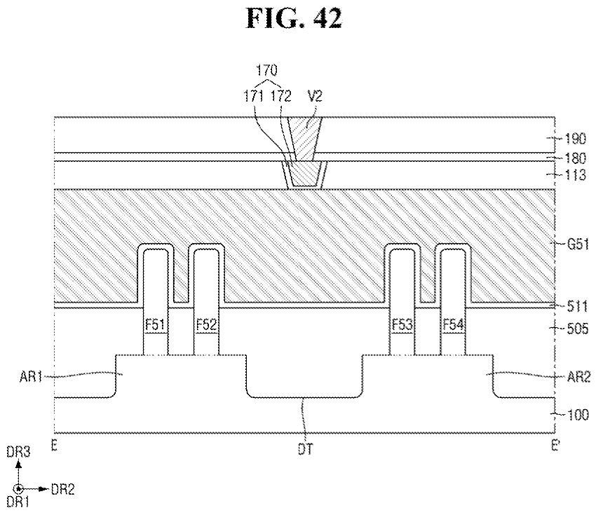

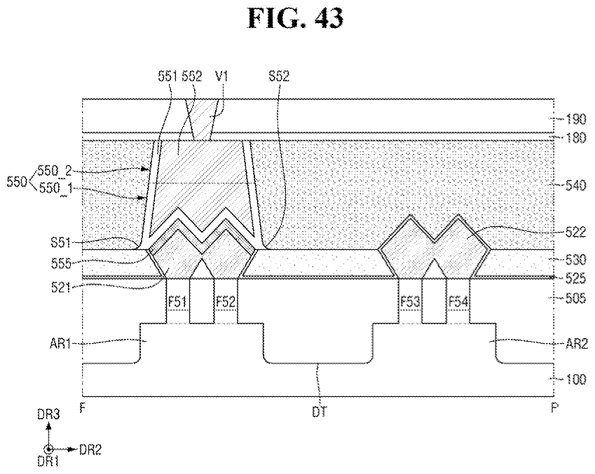

FIG. 40 is a layout view of a semiconductor device according to some embodiments of the present disclosure. FIG. 41 is a cross-sectional view taken along line D-D′ of FIG. 40. FIG. 42 is a cross-sectional view taken along line E-E′ of FIG. 40. FIG. 43 is a cross-sectional view taken along line F-F′ of FIG. 40.

Referring to FIGS. 40 to 43, a semiconductor device according to some embodiments of the present disclosure includes a fin-type transistor (FinFET). For example, a semiconductor device according to some embodiments of the present disclosure includes a substrate 100, a first active region AR1 and a second active region AR2, first to fourth active patterns F51, F52, F53 and F54, a field insulating layer 505, first to third gate electrodes G51, G52 and G53, a gate insulating layer 511, a gate spacer 512, a capping pattern 113, a first source/drain region 521, a second source/drain region 522, a first etch stop layer 525, a first interlayer insulating layer 530, a second interlayer insulating layer 540, a first source/drain contact 550, a silicide layer 555, a second source/drain contact 560, a gate contact 170, a second etch stop layer 180, a third interlayer insulating layer 190, a first via V1, and second via V2.

Each of the first active region AR1 and the second active region AR2 is disposed on the substrate 100. Each of the first active region AR1 and the second active region AR2 protrudes from the substrate 100 in the vertical direction DR3. Each of the first active region AR1 and the second active region AR2 is surrounded by a deep trench DT formed on the substrate 100. Each of the first active region AR2 and the second active region AR2 extends in the first horizontal direction DR1. The second active region AR2 is spaced apart from the first active region AR1 in the second horizontal direction DR2.

Each of the first and second active patterns FS1 and F52 is disposed on the first active region AR1. Each of the first and second active patterns F51 and F52 protrudes in the vertical direction DR3 from the first active region AR1. Each of the first and second active patterns F51 and F52 extends in the first horizontal direction DR1. The second active pattern F52 is spaced apart from the first active pattern F51 in the second horizontal direction DR2.

Each of the third and fourth active patterns F53 and F54 is disposed on the second active region AR2. Each of the third and fourth active patterns F53 and F54 protrudes in the vertical direction DR3 from the second active region AR2. Each of the third and fourth active patterns F53 and F54 extends in the first horizontal direction DR1. The fourth active pattern F54 is spaced apart from the third active pattern F53 in the second horizontal direction DR2.

The field insulating layer 505 is disposed on the substrate 100. The field insulating layer 505 surrounds a sidewall of each of the first to fourth active patterns F51, F52, F53 and F54 and the first and second active regions AR1 and AR2. The field insulating layer 505 fills the deep trench DT formed on the substrate 100. Each of the first to fourth active patterns F51, F52, F53 and F54 protrudes more in the vertical direction DR3 than an upper surface of the field insulating layer 505.

Each of the first to third gate electrodes G51, G52 and G53 extends in the second horizontal direction DR2 on the field insulating layer 505 and the first to fourth active patterns F51, F52, F53 and F54. The second gate electrode G52 is spaced apart from the first gate electrode G51 in the first horizontal direction DR1. The third gate electrode G53 is spaced apart from the second gate electrode G52 in the first horizontal direction DR1.

The gate spacer 512 extends in the second horizontal direction DR2 along a sidewall of each of the first to third gate electrodes G51, G52 and G53 on the field insulating layer 505. The gate spacer 512 extends in the second horizontal direction DR2 along the sidewall of each of the first to third gate electrodes G51, G52 and G53 on the first to fourth active patterns F51, F52, F53 and F54.

The gate insulating layer 511 is disposed between each of the first to third gate electrodes GS1, G52 and G53 and the gate spacer 512. The gate insulating layer 511 is disposed between each of the first to third gate electrodes G51, G52 and G53 and each of the first to fourth active patterns F51, F52, F53 and F54. The gate insulating layer 511 is disposed between each of the first to third gate electrodes G51, G52 and G53 and the field insulating layer 505.

The first source/drain region 521 is disposed on at least one side of each of the first to third gate electrodes G51, G52 and G53 on each of the first and second active patterns F51 and F52. The second source/drain region 522 is disposed on at least one side of each of the first to third gate electrodes GS1, G52 and G53 on each of the third and fourth active patterns F53 and F54.

The first source/drain region 521 on the first and second active patterns F51 and F52 has a merged shape. The second source/drain region 522 on the third and fourth active patterns F53 and F54 also has a merged shape.

The first interlayer insulating layer 530 is disposed on the field insulating layer 505. The first interlayer insulating layer 530 surrounds a sidewall of a lower portion each of the first and second source/drain regions 521 and 522. An upper surface of each of the first and second source/drain regions 521 and 522 is higher than that of the first interlayer insulating layer 530.

The second interlayer insulating layer 540 is disposed on the first interlayer insulating layer 530. The second interlayer insulating layer 540 surrounds the sidewall of an upper portion of each of the first and second source/drain regions 521 and 522. The upper surface of each of the first and second source/drain regions 521 and 522 is lower than that of the second interlayer insulating layer 540.

The first etch stop layer 525 is disposed between the field insulating layer 505 and the first interlayer insulating layer 530. The first etch stop layer 525 is disposed along a surface of each of the first and second source/drain regions 521 and 522. However, the first etch stop layer 525 is not disposed between the first source/drain contact 550 and the first source/drain region 521 and between the second source/drain contact 560 and the second source/drain region 522.

The first source/drain contact 550 penetrates through the second interlayer insulating layer 540 in the vertical direction DR3 and is electrically connected to the first source/drain region 521. For example, the first source/drain contact 550 is disposed on the first source/drain region 521 between the second gate electrode G52 and the third gate electrode G53. The first source/drain contact 550 surrounds the sidewall of an upper portion the first source/drain region 521. A portion of the first source/drain contact 550 is disposed between the first source/drain region 521 and the second interlayer insulating layer 540. The first source/drain contact 550 is in contact with each of the gate spacer 512 and the capping pattern 113. The first source/drain contact 550 includes a first barrier layer 551 and a first filling layer 552 disposed on the first barrier layer 551 and that fills a space formed by the first barrier layer 551.

The first source/drain contact 550 includes a first portion 550_1, a second portion 550_2, a first skirt S51, and a second skirt S52. Sidewalls of the first portion 550_1 of the first source/drain contact 550 are continuous with sidewalls of the second portion 550_2 of the first source/drain contact 550.

The first skirt S51 protrudes in the second direction DR2 from one sidewall below the first portion 550_1 of the first source/drain contact 550 toward the second interlayer insulating layer 540. Further, the second skirt S52 protrudes in an opposite second direction DR2 from the other sidewall below the first portion 550_1 of the first source/drain contact 550 toward the second interlayer insulating layer 540.

The second source/drain contact 560 is disposed on the second source/drain region 522 between the first gate electrode G51 and the second gate electrode G52. The silicide layer 555 is disposed between the first source/drain region 521 and the first source/drain contact 550.

Although embodiments according to the present disclosure have been described with reference to the accompanying drawings, embodiments of the present disclosure can be manufactured in various forms without being limited to above-described embodiments, and a person with ordinary skill in the art to which the present disclosure pertains can understand that embodiments of the present disclosure can take other specific forms without departing from technical spirits and characteristics of embodiments of the present disclosure. Thus, above embodiments are to be considered in all respects as illustrative and not restrictive.

What is claimed is:

1. A semiconductor device, comprising:
a substrate;
an active pattern disposed on the substrate and that extends in a first horizontal direction;
a field insulating layer disposed on the substrate and that surrounds a sidewall of the active pattern;
a gate electrode disposed on the field insulating layer and that extends in a second horizontal direction different from the first horizontal direction;
a source/drain region disposed on at least one side of the gate electrode;
a first interlayer insulating layer disposed on the field insulating layer and that surrounds a portion of a sidewall of the source/drain region;
a second interlayer insulating layer disposed on the first interlayer insulating layer and that surrounds a sidewall of the gate electrode; and
a source/drain contact that penetrates through the second interlayer insulating layer in a vertical direction and is electrically connected to the source/drain region, wherein the source/drain contact includes a skirt that protrudes from a lower sidewall toward the second interlayer insulating layer in a horizontal direction.

2. The semiconductor device of claim 1, wherein a width of a lower surface of the source/drain contact in the second horizontal direction is greater than a width of an upper surface of the source/drain contact in the second horizontal direction.

3. The semiconductor device of claim 1, wherein the source/drain contact includes a first portion disposed on the source/drain region and a second portion disposed on the first portion,
the first portion includes first and second sidewalls that oppose each other in the second horizontal direction, and the second portion includes first and second sidewalls that oppose each other in the second horizontal direction, and
the first sidewall of the first portion is continuous with the first sidewall of the second portion, and the second sidewall of the first portion is continuous with the second sidewall of the second portion.

4. The semiconductor device of claim 3, wherein the skirt includes:
a first skirt that protrudes from the first sidewall of the first portion; and
a second skirt that protrudes from the second sidewall of the first portion.

5. The semiconductor device of claim 1, further comprising a capping pattern disposed on the gate electrode and that extends in the second horizontal direction, wherein the capping pattern is in contact with a sidewall of the source/drain contact.

6. The semiconductor device of claim 1, wherein a portion of the source/drain contact is disposed between the source/drain region and the second interlayer insulating layer.

7. The semiconductor device of claim 1, wherein the skirt is in contact with an upper surface of the first interlayer insulating layer.

8. The semiconductor device of claim 1, further comprising a plurality of nanosheets stacked and spaced apart from each other in the vertical direction on the active pattern and surrounded by the gate electrode.

9. The semiconductor device of claim 1, wherein the first interlayer insulating layer and the second interlayer insulating layer include materials that differ from each other.

10. The semiconductor device of claim 1, wherein the source/drain contact includes a first portion disposed on the source/drain region and a second portion disposed on the first portion, and
a portion of an upper surface of the first portion is in contact with the second interlayer insulating layer.

11. The semiconductor device of claim 1, further comprising:
a silicide layer disposed between the source/drain region and the source/drain contact; and
an etch stop layer disposed between the first interlayer insulating layer and the silicide layer.

12. A semiconductor device, comprising:
a substrate;
an active pattern disposed on the substrate and that extends in a first horizontal direction;
a field insulating layer disposed on the substrate and that surrounds a sidewall of the active pattern;
a gate electrode disposed on the field insulating layer and that extends in a second horizontal direction different from the first horizontal direction;
a source/drain region disposed on at least one side of the gate electrode;
a first interlayer insulating layer disposed on the field insulating layer and that surrounds a portion of a sidewall of the source/drain region;
a second interlayer insulating layer disposed on the first interlayer insulating layer and that surrounds a sidewall of the gate electrode; and
a source/drain contact that penetrates through the second interlayer insulating layer in a vertical direction and is electrically connected to the source/drain region, wherein the source/drain contact includes a first portion disposed on the source/drain region and a second portion disposed on the first portion,
wherein the first portion includes first and second sidewalls that oppose each other in the second horizontal direction, and the second portion includes first and second sidewalls that oppose each other in the second horizontal direction,
the first sidewall of the first portion is continuous with the first sidewall of the second portion, and the second sidewall of the first portion is continuous with the second sidewall of the second portion, and
a width of a lower surface of the first portion in the second horizontal direction is greater than a width of a lower surface of the second portion in the second horizontal direction.

13. The semiconductor device of claim 12, wherein the source/drain contact further includes a skirt that protrudes from a lower sidewall of the first portion toward the second interlayer insulating layer in a horizontal direction.

14. The semiconductor device of claim 13, wherein the skirt includes:
a first skirt that protrudes from the first sidewall of the first portion; and
a second skirt that protrudes from the second sidewall of the first portion.

15. The semiconductor device of claim 13, wherein the skirt is in contact with an upper surface of the first interlayer insulating layer.

16. The semiconductor device of claim 12, further comprising a capping pattern disposed on the gate electrode and that extends in the second horizontal direction, wherein the capping pattern is in contact with a sidewall of the source/drain contact.

17. The semiconductor device of claim 12, wherein the first interlayer insulating layer and the second interlayer insulating layer include materials that differ from each other.

18. The semiconductor device of claim 12, wherein a portion of an upper surface of the first portion is in contact with the second interlayer insulating layer.

19. A semiconductor device, comprising:
a substrate;
an active pattern disposed on the substrate and that extends in a first horizontal direction;
a field insulating layer disposed on the substrate and that surrounds a sidewall of the active pattern;
a gate electrode disposed on the field insulating layer and that extends in a second horizontal direction different from the first horizontal direction;
a plurality of nanosheets stacked and spaced apart from each other in a vertical direction on the active pattern and surrounded by the gate electrode;
a source/drain region disposed on at least one side of the gate electrode;
a first interlayer insulating layer disposed on the field insulating layer and that surrounds a portion of a sidewall of the source/drain region;
a second interlayer insulating layer disposed on the first interlayer insulating layer and that surrounds a sidewall of the gate electrode; and
a source/drain contact that penetrates through the second interlayer insulating layer in a vertical direction and is electrically connected to the source/drain region, wherein the source/drain contact includes a first portion disposed on the source/drain region, a second portion disposed on the first portion, wherein the source/drain contact includes a skirt that protrudes from a lower sidewall of the first portion toward the second interlayer insulating layer in a horizontal direction,
wherein the first portion includes first and second sidewalls that oppose each other in the second horizontal direction, and the second portion includes first and second sidewalls that oppose each other in the second horizontal direction,
the first sidewall of the first portion is continuous with the first sidewall of the second portion, and the second sidewall of the first portion is continuous with the second sidewall of the second portion, and
a width of a lower surface of the first portion in the second horizontal direction is greater than a width of a lower surface of the second portion in the second horizontal direction.

20. The semiconductor device of claim 19, wherein the first interlayer insulating layer and the second interlayer insulating layer include materials that differ from each other.
